(19) United States
(12) Patent Application Publication
(10) Pub. No.: US 2025/0040354 A1
(43) Pub. Date: Jan. 30, 2025

(54) DISPLAY PANEL AND METHOD FOR MANUFACTURING THE SAME

(71) Applicant: Samsung Display Co., LTD., Yongin-si (KR)

(72) Inventors: YOUNGSEOK BAEK, Yongin-si (KR); CHONGSUP CHANG, Yongin-si (KR)

(21) Appl. No.: 18/783,595

(22) Filed: Jul. 25, 2024

(30) Foreign Application Priority Data
Jul. 26, 2023 (KR) 10-2023-0097545

(51) Int. Cl. H10K 59/122; H10K 59/12; H10K 59/80; H10K 59/88; H10K 71/60

(52) U.S. Cl. CPC H10K 59/122; H10K 59/1201; H10K 59/873; H10K 59/88; H10K 71/60

(57) ABSTRACT

Provided is a display panel including a base layer in which an emission area and a peripheral area adjacent to the emission area are defined, an insulation layer disposed on the base layer and in which a groove overlapping the emission area is defined, a pixel defining film disposed on the insulation layer and in which an emission opening portion overlapping the groove is defined, a partition wall disposed on the pixel defining film and in which a partition wall opening portion overlapping the emission opening portion is defined, and a light emitting element disposed in the partition wall opening portion, the light emitting element including an anode, an intermediate layer, and a cathode that is in contact with the partition wall. The insulation layer includes an inner side surface defining the groove and is inclined at a first angle with respect to a top surface of the base layer.

This application claims priority to Korean Patent Application No. 10-2023-0097545, filed on Jul. 26, 2023, and all the benefits accruing therefrom under 35 U.S.C. § 119, the content of which in its entirety is herein incorporated by reference.

### BACKGROUND

### Field

The present disclosure herein relates to a display panel and a method for manufacturing the same, and more particularly, to a display panel with improved reliability and a method for manufacturing the display panel.

### Description of the Related Art

Display devices such as, for example, televisions, monitors, smartphones, and tablet computers, which provide users with images, may include display panels that display the images. Various display panels such as, for example, liquid crystal display panels, organic light emitting display panels, electro wetting display panels, and electrophoretic display panels, have been developed as display panels.

An organic light emitting display panel may include an anode, a cathode, and an emission pattern. In some cases, the emission pattern may be separated for each emission area, and the cathode may supply a common voltage to each emission area.

### SUMMARY

The present disclosure provides a display panel, which provides a light emitting element without using a metal mask and has improved process reliability, and a method for manufacturing the display panel.

An embodiment supported by aspects of the present disclosure provides a display panel including a base layer in which an emission area and a peripheral area adjacent to the emission area are defined, an insulation layer disposed on the base layer and in which a groove overlapping the emission area is defined, a pixel defining film disposed on the insulation layer and in which an emission opening portion overlapping the groove is defined, a partition wall disposed on the pixel defining film and in which a partition wall opening portion overlapping the emission opening portion is defined, and a light emitting element disposed in the partition wall opening portion, the light emitting element including an anode, an intermediate layer, and a cathode that is in contact with the partition wall. The insulation layer includes an inner side surface defining the groove and inclined at a first angle with respect to a top surface of the base layer, and at least a portion of the partition wall has a shape extending along the inner side surface.

In an embodiment, the partition wall may include a tip portion extending along the inner side surface and protruding toward a center of the anode.

In an embodiment, the tip portion may include a first tip portion, which extends along the inner side surface and is inclined at a second angle with respect to the top surface of the base layer, and a second tip portion which extends from the first tip portion in a direction parallel to the top surface of the base layer.

In an embodiment, the second angle may be substantially equal to the first angle.

In an embodiment, the partition wall may include a first partition wall layer disposed on the pixel defining film and is in contact with the cathode, and a second partition wall layer disposed on the first partition wall layer and including a tip portion protruding from an inner side surface of the first partition wall layer.

In an embodiment, the second partition wall layer may include a first portion overlapping the peripheral area and having a flat top surface, a second portion extending from the first portion along the inner side surface, and a third portion extending from the second portion in a direction parallel to the top surface of the base layer, and a sub-portion of the second portion and a sub-portion of the third portion may define the tip portion.

In an embodiment, the first partition wall layer may include a first partition wall portion disposed between the first portion and the pixel defining film, and a second partition wall portion disposed between the second portion and the inner side surface.

In an embodiment, a length of the tip portion may be about 0.6 μm to about 1.5 μm.

In an embodiment, at least a portion of the pixel defining film may have a shape extending along the inner side surface.

In an embodiment, the display panel may further include a sacrificial pattern disposed in the groove, and between the anode and the pixel defining film, and in which a sacrificial opening portion overlapping the emission opening portion is defined.

In an embodiment, the insulation layer may include a top surface including a first surface overlapping the peripheral area, and a second surface that has a height difference with the first surface and defines the groove together with the inner side surface.

In an embodiment, the display panel may further include an encapsulation layer disposed on the light emitting element and including a plurality of thin films, and the encapsulation layer may include an inorganic encapsulation pattern which covers the light emitting element and includes a portion that is in contact with the partition wall.

In an embodiment, the display panel may further include a first dummy pattern disposed on the partition wall and including the same material as an emission pattern included in the display panel, wherein the second dummy pattern is spaced apart from the emission pattern. The display panel may further include a second dummy pattern disposed on the first dummy pattern and including a same material as the cathode, wherein the second dummy pattern is spaced apart from the cathode.

In an embodiment supported by aspects of the present disclosure, a display panel includes a base layer in which an emission area and a peripheral area adjacent to the emission area are defined, an anode disposed on the base layer, a pixel defining film in which an emission opening portion that exposes at least a portion of the anode and overlaps the emission area is defined, a partition wall disposed on the pixel defining film and in which a partition wall opening portion overlapping the emission opening portion is defined, an emission pattern disposed in the partition wall opening portion, and a cathode that is disposed in the partition wall opening portion and is in contact with the partition wall. The partition wall includes a tip portion protruding toward a center of the anode, and the tip portion includes a first tip portion inclined at a predetermined angle with respect to the top surface of the base layer, and a second tip portion extending from the first tip portion in a direction parallel to the top surface of the base layer.

In an embodiment supported by aspects of the present disclosure, a method for manufacturing a display panel is described, the method including preparing a base layer in which an emission area and a peripheral area adjacent to the emission area are defined, forming, on the base layer, an insulation layer in which a groove overlapping the emission area is defined, and forming an anode in the groove defined in the insulation layer. The method includes forming, on the insulation layer, a pixel defining film in which an emission opening portion overlapping the anode is defined. The method includes forming, on the pixel defining film, a partition wall in which a partition wall opening portion overlapping the emission opening portion is defined. The method includes forming an emission pattern including at least a portion disposed in the emission opening portion, and forming a cathode including at least a portion disposed in the partition wall opening portion, where the cathode is in contact with an inner side surface of the partition wall that defines the partition wall opening portion. The insulation layer includes an inner side surface that defines the groove and is inclined at a first angle with respect to a top surface of the base layer, and at least a portion of the partition wall has a shape extending along the inner side surface.

In an embodiment, the forming of the anode may include forming a conductive layer on the insulation layer, and patterning the conductive layer such that the anode overlapping the groove is formed.

In an embodiment, the method may further include, before the forming of the pixel defining film, forming a preliminary sacrificial pattern on the anode, and the forming of the anode and the forming of the preliminary sacrificial pattern may be performed through a same process.

In an embodiment, the forming of the anode and the preliminary sacrificial pattern may include forming a conductive layer on the insulation layer, forming a sacrificial layer on the conductive layer, and patterning the conductive layer and the sacrificial layer such that the anode and the preliminary sacrificial pattern are formed, where the anode and the preliminary sacrificial pattern overlap the groove.

In an embodiment, the method may further include, forming the sacrificial pattern in which a sacrificial opening portion overlapping the partition wall opening portion is defined, where the forming of the sacrificial pattern includes etching the preliminary sacrificial pattern and is after the forming of the partition wall.

In an embodiment, in the forming of the partition wall, a portion of the preliminary sacrificial pattern may be removed to form the sacrificial pattern in which a sacrificial opening portion corresponding to the emission opening portion is defined.

In an embodiment, the forming of the insulation layer may include forming a preliminary insulation layer on the base layer, exposing the preliminary insulation layer to light by using a mask in which a transmission area corresponding to the emission area and a semi-transmission area corresponding to the peripheral area are defined, and developing the preliminary insulation layer.

### BRIEF DESCRIPTION OF THE DRAWINGS

The accompanying drawings are included to provide a further understanding supported by aspects of the present disclosure, and are incorporated in and constitute a part of this specification. The drawings illustrate embodiments supported by aspects of the present disclosure and, together with the description, serve to explain principles supported by aspects of the present disclosure. In the drawings:

FIG. 1A is a perspective view of a display device according to an embodiment supported by aspects of the present disclosure;

FIG. 1B is an exploded perspective view of a display device according to an embodiment supported by aspects of the present disclosure;

FIG. 2 is a cross-sectional view of a display panel according to an embodiment supported by aspects of the present disclosure;

FIG. 3 is a plan view of a display panel according to an embodiment supported by aspects of the present disclosure;

FIG. 4 is an enlarged plan view of a portion of a display area of a display panel according to an embodiment supported by aspects of the present disclosure;

FIG. 5A is a cross-sectional view of the display panel according to an embodiment supported by aspects of the present disclosure taken along line I-I′ in FIG. 4;

FIG. 5B is a cross-sectional view illustrating some components of a display panel according to an embodiment supported by aspects of the present disclosure;

FIG. 5C is an enlarged cross-sectional view of area AA′ of the display panel according to an embodiment supported by aspects of the present disclosure in FIG. 5B;

FIG. 5D is a cross-sectional view of the display panel according to an embodiment supported by aspects of the present disclosure taken along line II-II′ in FIG. 4;

FIG. 6A is a cross-sectional view of the display panel according to an embodiment supported by aspects of the present disclosure taken along line I-I′ in FIG. 4;

FIG. 6B is a cross-sectional view of the display panel according to an embodiment supported by aspects of the present disclosure taken along line II-II′ in FIG. 4;

FIGS. 7A to 7Q are cross-sectional views illustrating some operations of a method for manufacturing a display panel according to an embodiment supported by aspects of the present disclosure; and

FIGS. 8A to 8D are cross-sectional views illustrating some operations of a method for manufacturing a display panel according to an embodiment supported by aspects of the present disclosure.

### DETAILED DESCRIPTION

In the present disclosure, it will be understood that when an element (or region, layer, section, and the like) is referred to as being “on”, “connected to” or “coupled to” another element, the element can be disposed directly on, connected or coupled to the other element or a third intervening elements may be disposed between the elements.

Like reference numbers or symbols refer to like elements throughout. In addition, in the drawings, the thickness, the ratio, and the dimension of elements are exaggerated for effective description of the technical contents. The term “and/or” includes one or more combinations which may be defined by relevant elements.

It will be understood that, although the terms first, second, and the like may be used herein to describe various elements, these elements should not be limited by these terms. These terms are examples used to distinguish one element from another element. For example, a first element could be termed a second element without departing from the teachings supported by aspects of the present disclosure, and similarly, a second element could be termed a first element. As used herein, the singular forms are intended to include the plural forms as well, unless the context clearly indicates otherwise.

In addition, the terms, such as, for example, “below”, “beneath”, “on” and “above”, are used for explaining the relation of elements shown in the drawings. The terms are relative concept and are explained based on the direction shown in the drawing.

It will be further understood that the terms such as, for example, “includes” and “has”, when used herein, specify the presence of stated features, numerals, steps, operations, elements, parts, or the combination thereof, but do not preclude the presence or addition of one or more other features, numerals, steps, operations, elements, parts, or the combination thereof.

As used herein, the term “being directly disposed” may mean that there is no additional layer, film, region, plate or the like between a part such as, for example, a layer, film, region, plate or the like and another part. For example, “being directly disposed” may mean that two layers or two members are disposed with no additional member such as, for example, an adhesive member.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially,” as used herein, may mean to a large or significant extent, for the most part, essentially, or the like. The term “substantially equal,” as used herein, means approximately or actually equal (e.g., within a threshold percent of equal). The term “substantially the same,” as used herein, means approximately or actually the same (e.g., within a threshold difference amount).

Unless otherwise defined, all terms (including technical and scientific terms) used herein have the same meaning as commonly understood by one of ordinary skill in the art to which the present disclosure belongs. It will be further understood that terms, such as, for example, those defined in commonly used dictionaries, should be interpreted as having a meaning that is consistent with their meaning in the context of the relevant art and will not be interpreted in an idealized or overly formal sense unless expressly so defined herein.

Hereinafter, embodiments supported by aspects of the present disclosure will be described with reference to the accompanying drawings.

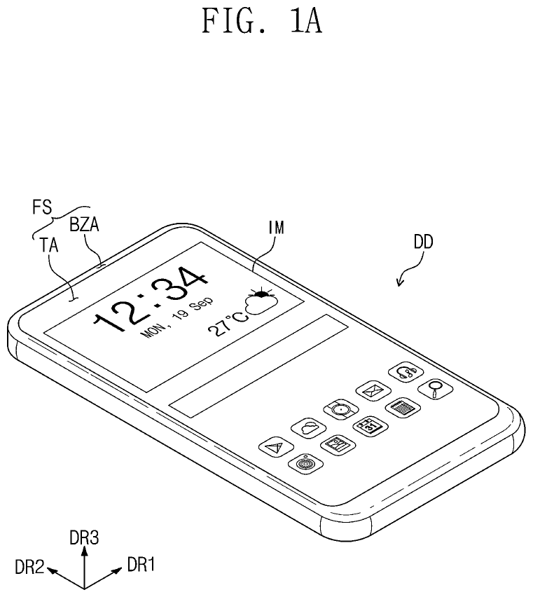

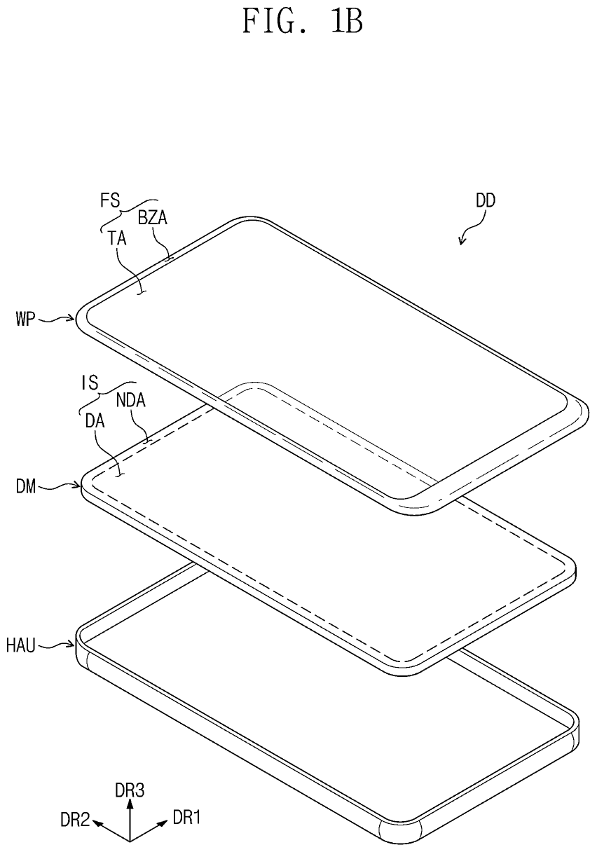

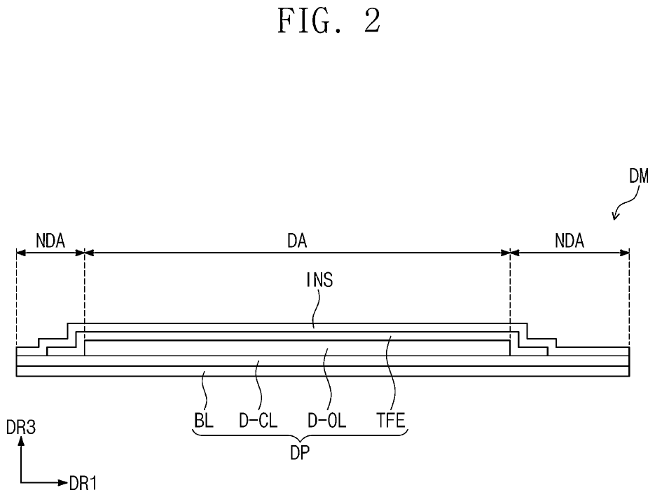

FIG. 1A is a perspective view of a display device according to an embodiment supported by aspects of the present disclosure. FIG. 1B is an exploded perspective view of a display device according to an embodiment supported by aspects of the present disclosure. FIG. 2 is a cross-sectional view of a display panel according to an embodiment supported by aspects of the present disclosure.

In an embodiment, a display device DD may be a large-sized display device such as, for example, a television, a monitor, or an outdoor billboard. The display device DD may also be a small and medium-sized display device such as, for example, a personal computer, a notebook computer, a personal digital assistant, a vehicle navigation unit, a game console, a smartphone, a tablet computer, and a camera. The foregoing devices are provided as examples, and the display device DD may also be employed as another display device without departing the scope of the present disclosure. In the example embodiment, a smartphone is illustrated as an example of the display device DD.

Referring to FIGS. 1A, 1B, and 2, the display device DD may display an image IM in a third direction DR3 on a display surface FS parallel to each of a first direction DR1 and a second direction DR2. The image IM may include a dynamic image, and in some cases, a still image. FIG. 1A illustrates a clock window and icons as an example of the image IM. The display surface FS on which the image IM is displayed may correspond to a front surface of the display device DD.

In the example embodiment, a front surface (or top surface) and a rear surface (or bottom surface) of each member is defined based on a direction in which the image IM is displayed. The front surface and the rear surface may oppose each other in the third direction DR3, and a normal direction to each of the front surface and the rear surface may be parallel to the third direction DR3. In some aspects, directions indicated by the first to third directions DR1, DR2 and DR3 are relative concepts and may be changed to other directions. The phrase “on a plane” used herein may mean a state when viewed in the third direction DR3 (e.g., according to a plan view).

As illustrated in FIG. 1B, the display device DD according to one or more embodiments may include a window WP, a display module DM, and a housing HAU. The window WP and the housing HAU may be coupled to each other to constitute an outer appearance of the display device DD.

The window WP may include an optically transparent insulation material. For example, the window WP may include glass or plastic. The front surface of the window WP may define the display surface FS of the display device DD. The display surface FS may include a transmission area TA and a bezel area BZA. The transmission area TA may be an optically transparent area. For example, the transmission area TA may be an area having a visible light transmittance of about 90% or higher.

The bezel area BZA may be an area having a relatively low light transmittance compared to the transmission area TA. The bezel area BZA may define a shape of the transmission area TA. The bezel area BZA may be adjacent to the transmission area TA and surround the transmission area TA. However, embodiments of the present disclosure are not limited thereto the example illustrated at FIG. 1B, and the bezel area BZA may be omitted in the window WP according to an embodiment supported by aspects of the present disclosure. The window WP may include at least one functional layer of an anti-fingerprint layer, a hard coating layer, or an anti-reflection layer, and is not limited to any one embodiment.

The display module DM may be disposed below the window WP. The display module DM may be a component that substantially generates the image IM. The image IM generated by the display module DM may be displayed on a display surface IS of the display module DM, and externally visible to a user through the transmission area TA.

The display module DM may include a display area DA and a non-display area NDA. The display area DA may be an area that is activated in response to an electrical signal. The non-display area NDA may be adjacent to the display area DA. The non-display area NDA may surround the display area DA. The non-display area NDA may be an area covered by the bezel area BZA, and may not be visible externally.

As illustrated in FIG. 2, the display module DM according to one or more embodiments may include may include a display panel DP and an input sensor INS. Although not separately illustrated, the display device DD according to an embodiment supported by aspects of the present disclosure may further include a protective member disposed on a bottom surface of the display panel DP. Additionally, or alternatively, the display device DD may further include an anti-reflection member and/or a window member that are disposed on a top surface of the input sensor INS.

The display panel DP may be a light emitting display panel, but is not particularly limited thereto. For example, the display panel DP may be an organic light emitting display panel or an inorganic light emitting display panel. An emission layer in the organic light emitting display panel includes an organic light emitting material. An emission layer in the inorganic light emitting display panel includes a quantum dot, a quantum rod, or a micro LED. Hereinafter, the display panel DP is described as the organic light emitting display panel.

The display panel DP may include a base layer BL. The display panel DP may include a circuit element layer D-CL, a display element layer D-OL, and an encapsulation layer TFE, which are disposed on the base layer BL. The input sensor INS may be disposed directly on the encapsulation layer TFE. In the present disclosure, the term “a component A being disposed directly on a component B” means that an intermediate component (e.g., an adhesive layer) is not disposed between the component A and the component B.

The base layer BL may include at least one plastic film. The base layer BL may be a flexible substrate and include a plastic substrate, a glass substrate, a metal substrate, an organic/inorganic composite material substrate, or the like. In the present disclosure, the display area DA and the non-display area NDA may be considered to be defined in the base layer BL. Here, components disposed on the base layer BL may be considered to overlap the display area DA or the non-display area NDA.

The circuit element layer D-CL includes at least one insulation layer and a circuit element. The insulation layer includes at least one inorganic layer and at least one organic layer. The circuit element includes signal lines, a driving circuit of a pixel, and the like.

The display element layer D-OL includes a partition wall and a light emitting element. The light emitting element may include an anode, an emission pattern, and a cathode, and the emission pattern may include at least an emission layer.

The encapsulation layer TFE includes a plurality of thin films. Some of the thin films are disposed to improve optical efficiency, and some of the thin films are disposed to protect organic light emitting diodes.

The input sensor INS obtains coordinate information of an external input. The input sensor INS may have a multilayer structure. The input sensor INS may include a conductive layer having a single-layer structure or a multilayer structure. The input sensor INS may include an insulation layer having a single-layer structure or a multilayer structure. The input sensor INS may detect an external input by using, for example, a capacitance method. In the present disclosure, however, the operation method of the input sensor INS is not particularly limited, and the input sensor INS according to an embodiment supported by aspects of the present disclosure may also detect an external input by using an electromagnetic induction method or a pressure detection method. In another embodiment supported by aspects of the present disclosure, the input sensor INS may be omitted.

As illustrated in FIG. 1B, the housing HAU may be coupled to the window WP. The housing HAU may be coupled to the window WP to provide a predetermined inner space. The display module DM may be accommodated in the inner space.

The housing HAU may include a material having relatively high rigidity. For example, the housing HAU may include a plurality of frames and/or plates, each of which includes glass, plastic, or metal or is formed of a combination of glass, plastic, and/or metal. The housing HAU may stably protect components, which are accommodated in the inner space, of the display device DD from external impact.

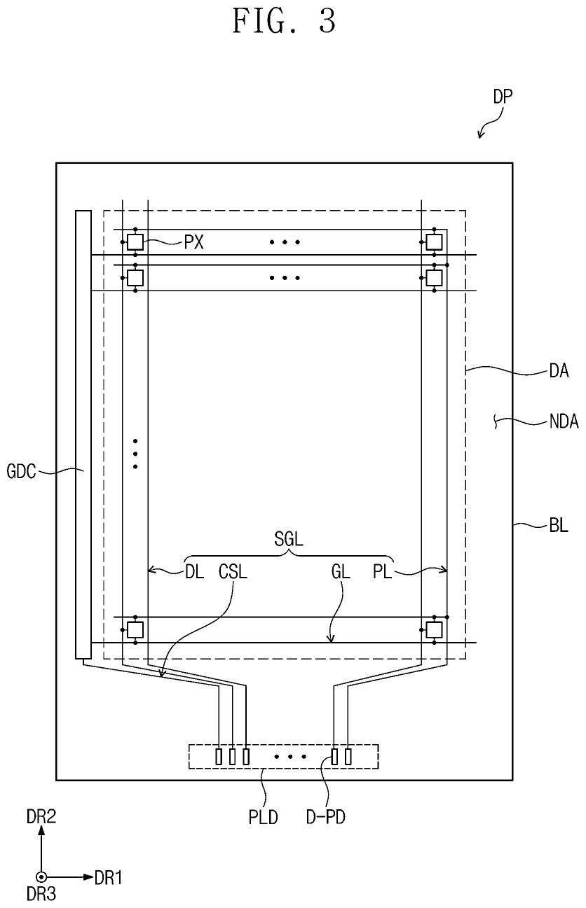

FIG. 3 is a plan view of a display panel according to an embodiment supported by aspects of the present disclosure.

Referring to FIG. 3, the display panel DP may include the base layer BL divided into the display area DA and the non-display area NDA, described with reference to FIG. 2.

The display panel DP may include pixels PX disposed in the display area DA, and signal lines SGL electrically connected to the pixels PX. The display panel DP may include a driving circuit GDC and a pad part PLD that are disposed in the non-display area NDA.

The pixels PX be arranged in the first direction DR1 and the second direction DR2. The pixels PX may include a plurality of pixel rows, which extend in the first direction DR1 and are arranged in the second direction DR2, and a plurality of pixel columns which extend in the second direction DR2 and are arranged in the first direction DR1.

The signal lines SGL may include gate lines GL, data lines DL, a power line PL, and a control signal line CSL. Each of the gate lines GL may be connected to a corresponding pixel PX among the pixels PX, and each of the data lines DL may be connected to a corresponding pixel PX among the pixels PX. The power line PL may be electrically connected to the pixels PX. The control signal line CSL may be connected to the driving circuit GDC and provide the driving circuit GDC with control signals.

The driving circuit GDC may include a gate driving circuit. The gate driving circuit may generate gate signals and sequentially output the generated gate signals to the gate lines GL. The gate driving circuit may further output another control signal to a pixel driving circuit.

The pad part PLD may be a portion to which a flexible circuit board is connected. The pad part PLD may include pixel pads D-PD, and the pixel pads D-PD may be pads for connecting the flexible circuit board to the display panel DP. Each of the pixel pads D-PD may be connected to a corresponding signal line among the signal lines SGL. The pixel pads D-PD may be connected to corresponding pixels PX through the signal lines SGL, respectively. In addition, one pixel pad of the pixel pads D-PD may be connected to the driving circuit GDC.

The pad part PLD may further include input pads. The input pads may be pads for connecting the flexible circuit board to the input sensor INS (see FIG. 2). However, embodiments supported by the present disclosure are not limited thereto, and the input pads may be disposed in the input sensor INS (see FIG. 2) and connected to a separate circuit board from the pixel pads D-PD. Alternatively, the input sensor INS (see FIG. 2) may be omitted, and the pads PD may not further include input pads.

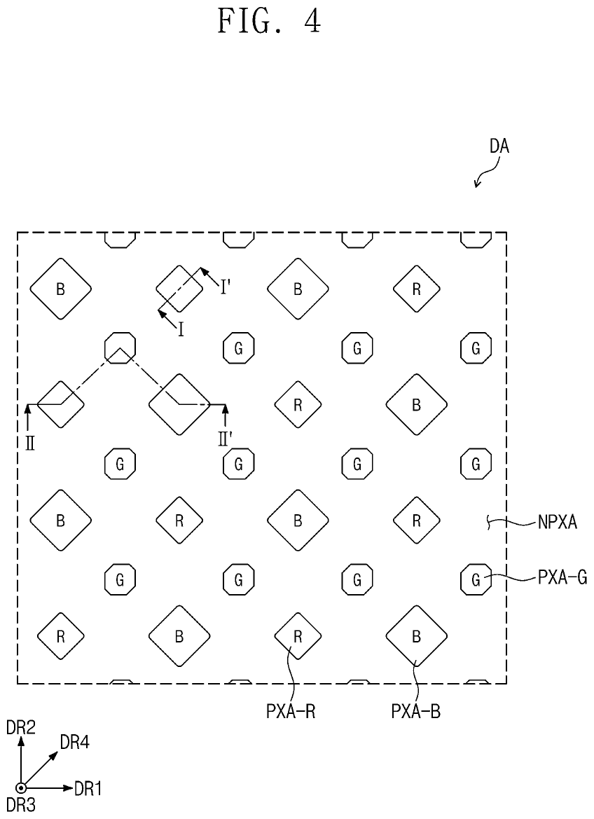

FIG. 4 is an enlarged plan view of a portion of a display area of a display panel according to an embodiment supported by aspects of the present disclosure. FIG. 4 illustrates a plane of the display module DM (see FIG. 2) when viewed on the display surface IS (see FIG. 2) of the display module DM (see FIG. 2), and illustrates arrangement of emission areas PXA-R, PXA-G and PXA-B.

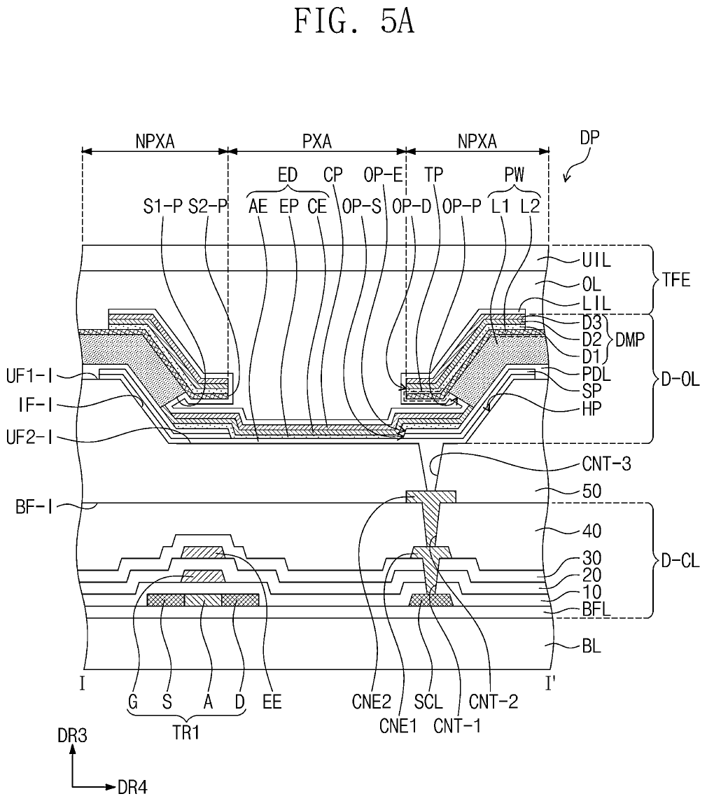

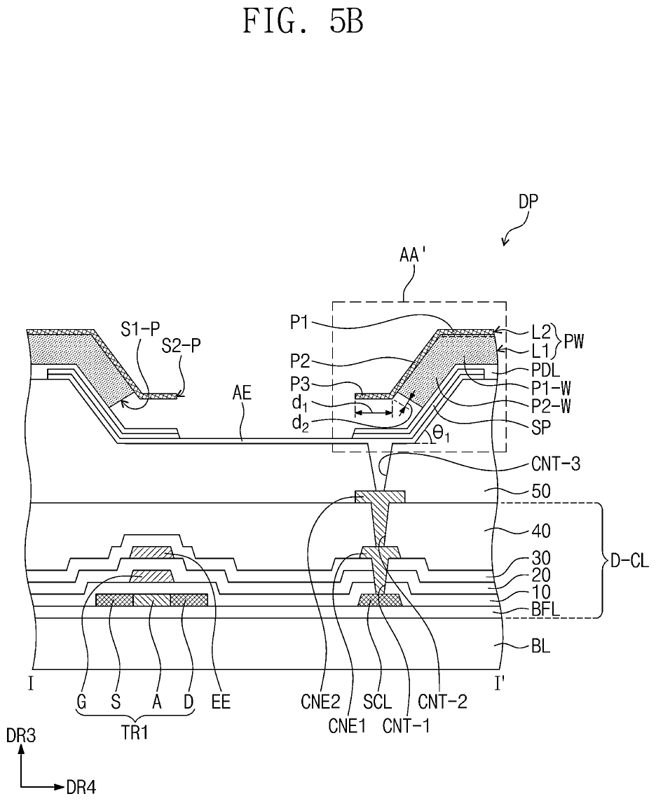

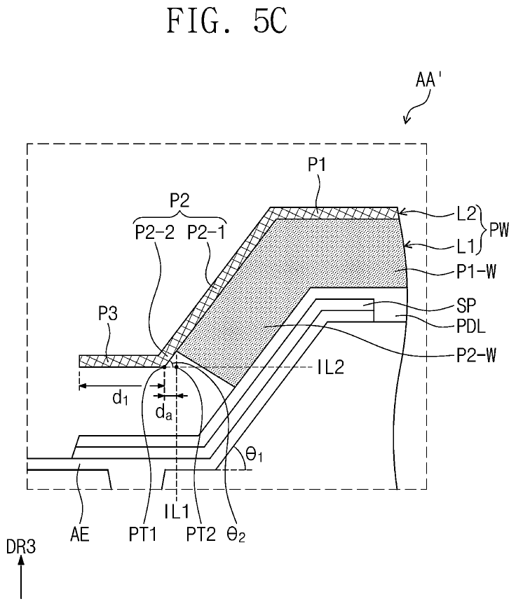

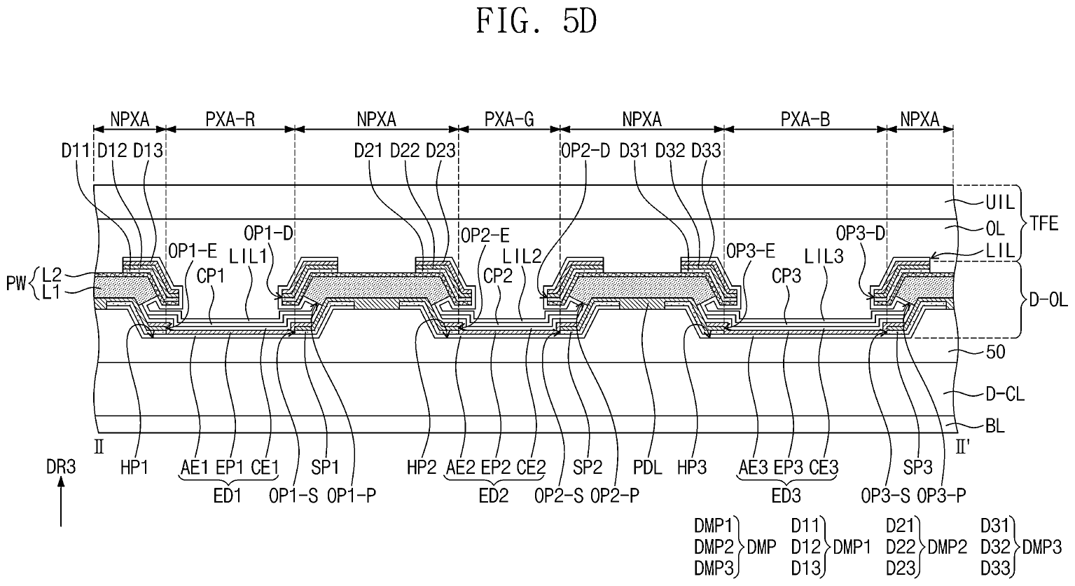

Referring to FIG. 4, the display area DA may include first to third emission areas PXA-R, PXA-G and PXA-B, and a peripheral area NPXA surrounding the first to third emission areas PXA-R, PXA-G and PXA-B. The first to third emission areas PXA-R, PXA-G and PXA-B may respectively correspond to areas from which light provided from light emitting elements ED1, ED2 and ED3 (see FIG. 5D) is emitted. The first to third emission areas PXA-R, PXA-G and PXA-B may be divided according to colors of light emitted toward the outside of the display module DM (see FIG. 2).

The first to third emission areas PXA-R, PXA-G and PXA-B may provide light of first to third colors different from each other, respectively. For example, the light of the first color may be red light, the light of the second color may be green light, and the light of the third color may be blue light. However, examples of the light of the first to third colors are not necessarily limited to the foregoing examples.

Each of the first to third emission areas PXA-R, PXA-G and PXA-B may be defined as an area in which a top surface of an anode is exposed by an emission opening portion to be described later herein. The peripheral area NPXA may set a boundary of each of the first to third emission areas PXA-R, PXA-G and PXA-B, and prevent mixture of colors between the first to third emission areas PXA-R, PXA-G and PXA-B.

Each of the first to third emission areas PXA-R, PXA-G and PXA-B may be provided in plurality to have a predetermined arrangement shape and be repeatedly disposed in the display area DA. For example, the first and third emission areas PXA-R and PXA-B may be alternately arranged in the first direction DR1 and constitute a “first group”. In an example, the second emission areas PXA-G may be arranged in the first direction DR1 and constitute a “second group”. Each of the “first group” and the “second group” may be provided in plurality, and the “first groups” and the “second groups” may be alternately arranged in the second direction DR2.

A second emission area PXA-G may be disposed such that the second emission area PXA-G is spaced apart from a first emission area PXA-R or a third emission area PXA-B in a fourth direction DR4. The fourth direction DR4 may be defined as a direction between the first and second directions DR1 and DR2.

The arrangement shape of the first to third emission areas PXA-R, PXA-G and PXA-B illustrated in FIG. 4 is an example and is not limited thereto. The first to third emission areas PXA-R, PXA-G and PXA-B may be arranged in various shapes. In an embodiment, the first to third emission areas PXA-R, PXA-G and PXA-B may have a PENTILE™ arrangement shape as illustrated in FIG. 4. Alternatively, the first to third emission areas PXA-R, PXA-G and PXA-B may have a stripe arrangement shape or a diamond (Diamond Pixel™) arrangement shape.

Each of the first to third emission areas PXA-R, PXA-G and PXA-B may have various shapes on a plane. For example, each of the first to third emission areas PXA-R, PXA-G and PXA-B may have a shape such as, for example, a polygonal, circular, or oval shape. As an example, FIG. 4 illustrates the first and third emission areas PXA-R and PXA-B each having a square (or rhombus) shape and the second emission area PXA-G having an octagonal shape on a plane.

The first to third emission areas PXA-R, PXA-G and PXA-B may have the same shape, or at least some of the first to third emission areas PXA-R, PXA-G and PXA-B may have a different shape on a plane. As an example, FIG. 4 illustrates the first and third emission areas PXA-R and PXA-B having the same shape, and the second emission area PXA-G having a different shape from the first and third emission areas PXA-R and PXA-B on a plane.

In some embodiments, at least some of the first to third emission areas PXA-R, PXA-G and PXA-B may have different areas on a plane. In an embodiment, the area of the first emission area PXA-R that emits red light may be greater than the area of the second emission area PXA-G that emits green light, and be less than the area of the third emission area PXA-B that emits blue light. However, the large-small relationship of the areas of the first to third emission areas PXA-R, PXA-G and PXA-B according to the colors of the emitted light is not limited thereto, and may be various according to the design of the display module DM (see FIG. 2). Embodiments supported by the present disclosure are not limited thereto, and the respective areas of the first to third emission areas PXA-R, PXA-G and PXA-B may be the same on a plane.

The shape, area, arrangement or the like of the first to third emission areas PXA-R, PXA-G and PXA-B of the display module DM (see FIG. 2) according to an embodiment supported by aspects of the present disclosure may be variously designed according to the color of the emitted light or the size or configuration of the display module DM (see FIG. 2), and are not limited to the embodiment illustrated in FIG. 4.

FIG. 5A is an enlarged cross-sectional view of a partial region of a display panel DP according to an embodiment supported by aspects of the present disclosure. FIG. 5A is a cross-sectional view of the display panel DP according to an embodiment supported by aspects of the present disclosure taken along line I-I′ in FIG. 4.

FIG. 5B is a cross-sectional view illustrating some components of a display panel DP according to an embodiment supported by aspects of the present disclosure. FIG. 5B illustrates some components of the display panel DP, which are disposed below a partition wall PW, among components of the display panel DP illustrated in FIG. 5A. That is, FIG. 5B illustrates the base layer BL, the circuit element layer D-CL, a fifth insulation layer 50, an anode AE, a pixel defining film PDL, and the partition wall PW, which are illustrated in FIG. 5A, and a cathode CE and the encapsulation layer TFE are omitted. FIG. 5C is an enlarged cross-sectional view of area AA′ of the display panel DP according to an embodiment supported by aspects of the present disclosure in FIG. 5B.

FIG. 5A illustrates an enlarged view of one emission area PXA in the display area DA (see FIG. 3), and the emission area PXA in FIG. 5A may correspond to any one of the first to third emission areas PXA-R, PXA-G and PXA-B in FIG. 4.

Referring to FIGS. 5A and 5B, the display panel DP may include the base layer BL, the circuit element layer DP-CL, the fifth insulation layer 50, the display element layer DP-OLED, and the encapsulation layer TFE.

The display panel DP may include a plurality of insulation layers, a semiconductor pattern, a conductive pattern, a signal line, and the like. In an example, the insulation layers, a semiconductor layer, and a conductive layer are formed through coating, deposition, or the like. Thereafter, the insulation layers, the semiconductor layer, and the conductive layer may be selectively patterned by performing a photolithography process and an etching process. The semiconductor pattern, the conductive pattern, the signal line, and the like, which are included in the circuit element layer D-CL or the display element layer D-OL, may be formed through the described processes (e.g., coating, deposition, photolithography, etching, and the like).

The circuit element layer D-CL may be disposed on the base layer BL. The circuit element layer D-CL may include a buffer layer BFL, a transistor TR1, a signal transmission region SCL, first to fourth insulation layers 10, 20, 30 and 40, an electrode EE, and a plurality of connection electrodes CNE1 and CNE2.

The buffer layer BFL may be disposed on the base layer BL. The buffer layer BFL may improve a bonding force between the base layer BL and the semiconductor pattern. The buffer layer BFL may include a silicon oxide layer and a silicon nitride layer (not illustrated). The silicon oxide layer and the silicon nitride layer may be stacked alternately.

The semiconductor pattern may be disposed on the buffer layer BFL. The semiconductor pattern may include polysilicon. However, embodiments supported by the present disclosure are not limited thereto, and the semiconductor pattern may also include amorphous silicon or a metal oxide. FIG. 5A illustrates a portion of the semiconductor pattern, and the semiconductor pattern may be further disposed in the plurality of emission areas PXA-R, PXA-G and PXA-B (see FIG. 4). The semiconductor pattern may be arranged over the plurality of emission areas PXA-R, PXA-G and PXA-B (see FIG. 4) according to a specific rule. The semiconductor pattern may have different electrical properties based on whether or not the semiconductor pattern is doped. The semiconductor pattern may include a first region having a high doping concentration and a second region having a low doping concentration. The first region may be doped with an n-type dopant or a p-type dopant. A p-type transistor may include the first region doped with the p-type dopant.

The first region may have higher conductivity than the second region and substantially serve as an electrode or a signal line. The second region may substantially serve as an active region (or channel) of a transistor. In other words, a portion of the semiconductor pattern may be an active region of a transistor, another portion may be a source or a drain of the transistor, and still another portion may be a conductive region.

A source S, an active region A, and a drain D of the transistor TR1 may be formed from the semiconductor pattern. FIG. 5A illustrates a portion of the signal transmission region SCL formed from the semiconductor pattern. Although not separately illustrated, the signal transmission region SCL may be connected to the drain D of the transistor TR1 on a plane.

The first to fourth insulation layers 10 to 40 may be disposed on the buffer layer BFL. Each of the first to fourth insulation layers 10 to 40 may be an inorganic layer or an organic layer.

The first insulation layer 10 may be disposed on the buffer layer BFL. A gate G may be disposed on the first insulation layer 10. The second insulation layer 20 may be disposed on the first insulation layer 10 such that the second insulation layer 20 covers the gate G. The electrode EE may be disposed on the second insulation layer 20. The third insulation layer 30 may be disposed on the second insulation layer 20 such that the third insulation layer 30 covers the electrode EE.

A first connection electrode CNE1 may be disposed on the third insulation layer 30. The first connection electrode CNE1 may be connected to the signal transmission region SCL through a contact hole CNT-1 passing through the first to third insulation layers 10 to 30. The fourth insulation layer 40 may be disposed on the third insulation layer 30 such that the fourth insulation layer 40 covers the first connection electrode CNE1. The fourth insulation layer 40 may be an organic layer.

A second connection electrode CNE2 may be disposed on the fourth insulation layer 40. The second connection electrode CNE2 may be connected to the first connection electrode CNE1 through a contact hole CNT-2 passing through the fourth insulation layer 40.

The fifth insulation layer 50 may be disposed on the fourth insulation layer 40. The fifth insulation layer 50 may cover the second connection electrode CNE2. The fifth insulation layer 50 may be an inorganic layer or an organic layer. In the example illustrated herein, the fifth insulation layer 50 may be constituted by a single film.

A groove HP may be defined in the fifth insulation layer 50. The groove HP may overlap the emission area PXA on a plane. As illustrated in FIG. 5A, a portion of the groove HP may overlap the peripheral area NPXA. The groove HP may be provided by removing a portion the fifth insulation layer 50 from a top surface of the fifth insulation layer 50. The anode AE may be disposed in the groove HP defined in the fifth insulation layer 50.

The top surface of the fifth insulation layer 50 may include a first surface UF1-I overlapping the peripheral area NPXA, and a second surface UF2-I overlapping the emission area PXA. The first surface UF1-I may have a stepped portion between the first surface UF1-I and the second surface UF2-I with respect to a thickness direction that is the third direction DR3. The stepped portion between the first surface UF1-I and the second surface UF2-I may be defined as a height difference between the first surface UF1-I and the second surface UF2-I in the third direction DR3. The top surface of the fifth insulation layer 50 may include an inner side surface IF-I that connects the first surface UF2-I to the second surface UF2-I. The inner side surface IF-I and the second surface UF2-I may define the groove HP.

The inner side surface IF-I that defines the groove HP may be provided to have a predetermined inclination. The inner side surface IF-I provided on the fifth insulation layer 50 may be an inclined surface. Accordingly, the groove HP may have a shape having a width that gradually increases from a lower portion of the fifth insulation layer 50 to an upper portion of the fifth insulation layer 50. The inner side surface IF-I of the groove HP may have a shape inclined at a first angle θ₁ with respect to a top surface of the base layer BL. The first angle θ₁ may be an acute angle. The first angle θ₁ may be greater than about 0° and less than about 90°. For example, the first angle θ₁ may be about 45° to about 85°.

The display element layer D-OL may be disposed on the fifth insulation layer 50. The display element layer D-OL may include a light emitting element ED, a sacrificial pattern SP, the pixel defining film PDL, the partition wall PW, and dummy patterns DMP.

The light emitting element ED may include the anode AE (or first electrode), an emission pattern EP, and the cathode CE (or second electrode). Each of first to third light emitting elements ED1, ED2 and ED3 (see FIG. 5D) to be described later herein may include substantially the same components as the light emitting element ED in FIG. 5A. The same/similar descriptions of the anode AE, the emission pattern EP, and the cathode CE may apply to an anode, an emission pattern, and a cathode of each of the first to third light emitting elements ED1, ED2 and ED3 (see FIG. 5D).

At least a portion of the anode AE may be disposed in the groove HP of the fifth insulation layer 50. The anode AE may be patterned and provided for each emission area PXA. The anode AE may be disposed on the second surface UF2-I and the inner side surface IF-I of the fifth insulation layer 50. Alternatively, or additionally, as illustrated in FIG. 5A, a portion of the anode AE may be disposed on the first surface UF1-I of the fifth insulation layer 50. That is, the anode AE may be provided to have a shape in which the anode AE is disposed on the first surface UF1-I, the second surface UF2-I, and the inner side surface IF-I, the anode AE does not continuously extend, and the anode AE has a portion disconnected on the first surface UF1-I. Expressed another way, the anode AE may partially extend over or partially overlap the first surface UF1-I. However, embodiments of the present disclosure are not limited thereto, and the anode AE may be disposed in the groove HP but not on the first surface UF1-I of the fifth insulation layer 50.

The anode AE may be a transmissive electrode, a semi-transmissive electrode, or a reflective electrode. The anode AE may have conductivity. For example, the anode AE may be formed of various materials such as, for example, a metal, a transparent conductive oxide (TCO), or a conductive polymeric material, such that the anode AE is capable of exhibiting conductivity. The anode AE may be connected to the second connection electrode CNE2 through a connection contact hole CNT-3 passing through and defined in the fifth insulation layer 50. Thus, the anode AE may be electrically connected to the signal transmission region SCL through the first and second connection electrodes CNE1 and CNE2, and the anode AE may be electrically connected to a corresponding circuit element.

The sacrificial pattern SP may be disposed between the anode AE and the pixel defining film PDL. The sacrificial pattern SP may be a portion of a layer provided to prevent the anode AE from being damaged during a process of forming a partition wall opening portion OP-P or the like to be described later herein. At least a portion of the sacrificial pattern SP may be disposed in the groove HP of the fifth insulation layer 50. The sacrificial pattern SP may be shaped such that at least a portion of the sacrificial pattern SP extends along the inner side surface IF-I of the fifth insulation layer 50. The sacrificial pattern SP may be disposed between the pixel defining film PDL and the inner side surface IF-I.

A sacrificial opening portion OP-S that exposes a portion of a top surface of the anode AE may be defined in the sacrificial pattern SP. The sacrificial opening portion OP-S may overlap an emission opening portion OP-E to be described later herein. The sacrificial pattern SP may include an amorphous transparent conductive oxide. For example, the sacrificial pattern SP may be a zinc oxide (ZnOₓ) doped with aluminum (Al).

The pixel defining film PDL may be disposed on the fifth insulation layer 50. The pixel defining film PDL may overlap the peripheral region NPXA on a plane. The pixel defining film PDL may be disposed on the first surface UF1-I of the fifth insulation layer 50. A portion of the pixel defining film PDL may be disposed in the groove HP of the fifth insulation layer 50. As illustrated in FIG. 5A, the pixel defining film PDL may have a shape disposed on the first surface UF1-I of the fifth insulation layer 50 and extending along the inner side surface IF-I of the fifth insulation layer 50. A portion of the pixel defining film PDL may be disposed on the second surface UF2-I of the fifth insulation layer 50. The emission opening portion OP-E may be defined in the pixel defining film PDL. The pixel defining film PDL may expose at least a portion of the anode AE through the emission opening portion OP-E. The emission opening portion OP-E may correspond to the sacrificial opening portion OP-S.

The area of the emission opening portion OP-E may be equal to or less than the area of the sacrificial opening portion OP-S on a plane. As illustrated in FIG. 5A, an inner side surface of the pixel defining film PDL, which defines the emission opening portion OP-E, may be substantially aligned with an inner side surface of the sacrificial pattern SP, which defines the sacrificial opening portion OP-S. However, embodiments supported by the present disclosure are not limited thereto, and the inner side surface of the pixel defining film PDL, which defines the emission opening portion OP-E, may be closer to a center of the anode AE than the inner side surface of the sacrificial pattern SP, which defines the sacrificial opening portion OP-S. Here, the emission area PXA may be considered to be a region of the anode AE, which is exposed by a corresponding sacrificial opening portion OP-S.

The pixel defining film PDL may include an inorganic insulation material. For example, the pixel defining film PDL may include a silicon oxide, a silicon nitride, or a combination of a silicon oxide and a silicon nitride. Accordingly, for example, moisture may be prevented from being released from the pixel defining film PDL during a subsequent patterning process. The pixel defining film PDL may be disposed between the anode AE and the partition wall PW and prevent an electrical connection between the anode AE and the partition wall PW.

The partition wall PW (or conductive partition wall) may be disposed on the pixel defining film PDL. A partition wall opening portion OP-P may be defined in the partition wall PW. The partition wall opening portion OP-P may correspond to the emission opening portion OP-E and may expose at least a portion of the anode AE.

At least a portion of the partition wall PW may have a shape extending along the inner side surface IF-I of the fifth insulation layer 50. Expressed another way, at least a portion of the partition wall PW may extend along the inner side surface IF-I of the fifth insulation layer 50. The partition wall PW may be divided into a plurality of portions in an extending direction. The partition wall PW may include a first flat portion extending in a first extension direction, a bending portion extending in a second extension direction, and a second flat portion extending in a third extension direction.

The first flat portion may be disposed on the first surface UF1-I of the fifth insulation layer 50. The first extension direction in which the first flat portion extends may be parallel to the top surface of the base layer BL. The bending portion may extend from an end of the first flat portion along the inner side surface IF-I of the fifth insulation layer 50. The second extension direction in which the bending portion extends may be parallel to a straight line inclined at a predetermined angle with respect to the top surface of the base layer BL. For example, the second extension direction may be the same as an extension direction of the inner side surface IF-I of the fifth insulation layer 50. That is, the angle at which the bending portion is inclined with respect to the top surface of the base layer BL may be substantially equal to the angle at which the inner side surface IF-I is inclined with respect to the top surface of the base layer BL.

The second flat portion may have a step difference from the first flat portion in the third direction DR3. The third extension direction in which the second flat portion extends may be parallel to the top surface of the base layer BL. The third extension direction in which the second flat portion extends may be substantially the same as the first extension direction in which the first flat portion extends. However, embodiments of the present disclosure are not limited thereto, and the third extension direction and the first extension direction may be different from each other.

The bending portion of the partition wall PW may have a shape inclined at a second angle θ₂ with respect to the top surface of the base layer BL. The second angle θ₂ may be an acute angle. The second angle θ₂ may be greater than about 0° and less than about 90°. For example, the second angle θ₂ may be about 45° to about 85°. In an embodiment, the second angle θ₂ may be substantially equal to the first angle θ₁.

The partition wall PW may have an undercut shape on a cross section. The partition wall PW may include a tip portion TP protruding from a portion of the partition wall PW on a cross section. The second flat portion and a portion of the bending portion of the partition wall PW may define the tip portion TP. The tip portion TP may include a first tip portion protruding from a portion of the partition wall PW in the bending portion in the second extension direction in which the bending portion extends, and the tip portion TP may include a second tip portion extending from the first tip portion in the third extension direction.

The second tip portion may correspond to the second flat portion described herein. The first tip portion may extend along the inner side surface IF-I, and the first tip portion may have a shape inclined at the second angle θ₂ with respect to the top surface of the base layer BL. The second tip portion may have a shape extending from the first tip portion in a direction DR4 parallel to the top surface of the base layer BL.

The partition wall PW may include a plurality of layers stacked in sequence, and among the stacked layers included in the plurality of layers, at least one of adjacent stacked layers may include a tip portion protruding from other adjacent stacked layers. For example, the uppermost layer of the plurality of layers included in the partition wall PW may include a tip portion protruding from the remaining adjacent layers included in the partition wall PW. As an example, FIG. 5A illustrates the partition wall PW in which two layers (e.g., a partition wall layer L1 and a second partition wall layer L2) are stacked, and a layer (e.g., second partition wall layer L2) disposed at an upper side of the two layers includes the protruding tip portion TP. However, embodiments of the present disclosure are not limited thereto. For example, the partition wall PW may have a structure in which three or more layers are stacked, and a layer disposed at the uppermost side of the three or more layers may include a protruding tip portion.

In an example embodiment, the partition wall PW may include a first partition wall layer L1 and a second partition wall layer L2. The first partition wall layer L1 may be disposed on the pixel defining film PDL, and the second partition wall layer L2 may be disposed on the first partition wall layer L1. The first partition wall layer L1 may be disposed directly on the pixel defining film PDL, and the second partition wall layer L2 may be disposed directly on the first partition wall layer L1.

The first partition wall layer L1 may have a thickness that is greater than a thickness of the second partition wall layer L2. In the present disclosure, the thickness of the first partition wall layer L1 may mean a distance between a bottom surface of the first partition wall layer L1 and a top surface of the first partition wall layer L1, measured with respect to the third direction DR3 on the first surface UF1-I of the fifth insulation layer 50. In addition, the thickness of the second partition wall layer L2 may mean a distance between a bottom surface of the second partition wall layer L2 and a top surface of the second partition wall layer L2, which are measured with respect to the third direction DR3 on the first surface UF1-I of the fifth insulation layer 50.

The first partition wall layer L1 may have a first conductivity, and the second partition wall layer L2 may have a second conductivity. In an embodiment, the first conductivity of the first partition wall layer L1 may be higher than the second conductivity of the second partition wall layer L2. In some embodiments, the first conductivity of the first partition wall layer L1 may be the same as the second conductivity of the second partition wall layer L2.

The second partition wall layer L2 may be formed of a material supportive of etching according to a first etch rate, and the first partition wall layer L1 may be formed of a material supportive of etching according to a second etch rate that is higher than the first etch rate. In the present disclosure, each of the first etch rate and the second etch rate may mean an etch rate supported by an etchant used in an “undercut etching process” to be described later herein. In the “undercut etching process”, due to the etch rate of the first partition wall layer L1 that is higher than the etch rate of the second partition wall layer L2, an inner side surface of the first partition wall layer L1 may be more etched than an inner side surface of the second partition wall layer L2. Alternatively, due to the second etch rate associated with the second partition wall layer L2, the second partition wall layer L2 may not be etched or may not be substantially etched in the “undercut etching process”.

The first partition wall layer L1 may be relatively recessed from the emission area PXA compared to the second partition wall layer L2. That is, for example, the first partition wall layer L1 may be undercut relative to the second partition wall layer L2. The first partition wall layer L1 may include a first inner side surface S1-P, and the second partition wall layer L2 may include a second inner side surface S2-P. The first inner side surface S1-P of the first partition wall layer L1 and the second inner side surface S2-P of the second partition wall layer L2 may define the partition wall opening portion OP-P of the partition wall PW.

The first inner side surface S1-P of the first partition wall layer L1 may be disposed relatively further inside than the emission area PXA, compared to the second inner side surface S2-P of the second partition wall layer L2. That is, for example, the first inner side surface S1-P resulting from the undercut etching process described herein may be recessed from the second inner side surface S2-P in a direction away from the emission area PXA. The first inner side surface S1-P may be undercut relative to the second inner side surface S2-P. A portion of the second partition wall layer L2, which protrudes from the first partition wall layer L1 toward the emission area PXA, may define the tip portion TP.

Referring to FIGS. 5B and 5C, the second partition wall layer L2 may include a plurality of first to third portions P1, P2 and P3. The second partition wall layer L2 may be divided into a first portion P1, a second portion P2, and a third portion P3. The first portion P3 may overlap the peripheral region NPXA. The first portion P1 of the second partition wall layer L2 may be a portion that is disposed on the first surface UF1-I of the fifth insulation layer 50. The first portion P1 may include a flat top surface.

The second portion P2 may be a portion extending from the first portion P1 along the inner side surface IF-I. The second portion P2 may have a shape extending from an end of the first portion P1 and inclined at the second angle θ₂ with respect to the top surface of the base layer BL. The third portion P3 may be a portion extending from an end of the second portion P2. The third portion P3 may have a stepped difference from the first portion P1 in the third direction DR3. The third portion P3 may have a shape extending at a third angle that is different from the second angle θ₂. The third angle may be less than the second angle θ₂. For example, the third angle may be 0° or about 0°. That is, for example, the third portion P3 may have a shape extending in a direction parallel to the top surface of the base layer BL.

The first partition wall layer L1 may include a plurality of partition wall portions P1-W and P2-W. For example, the first partition wall layer L1 may include a first partition wall portion P1-W and a second partition wall portion P2-W. The first partition wall portion P1-W may be disposed between the first portion P1 of the second partition wall layer L2 and the pixel defining film PDL. The first partition wall portion P1-W may overlap the peripheral region NPXA.

The second partition wall portion P2-W may be a portion extending from the first partition wall portion P1-W along the inner side surface IF-I. The second partition wall portion P2-W may be disposed between the second portion P2 of the second partition wall layer L2 and the inner side surface IF-I of the fifth insulation layer 50. The second partition wall portion P2-W may have a shape extending from an end of the first partition wall portion P1-W and inclined at the second angle θ₂ with respect to the top surface of the base layer BL.

The first partition wall portion P1-W of the first partition wall layer L1 may include a first bottom surface adjacent to the pixel defining film PDL, and the first partition wall portion P1-W may include a first top surface opposing the first bottom surface in the third direction DR3. The second partition wall portion P2-W of the first partition wall layer L1 may include a second bottom surface, which extends from the first bottom surface along the inner side surface IF-I. The second partition wall portion P2-W of the first partition wall layer L1 may include a second top surface, which opposes the second bottom surface and extends from the first top surface along the inner side surface IF-I. The second partition wall portion P2-W of the first partition wall layer L1 may include a connection surface which connects the second bottom surface to the second top surface. Each of the second bottom surface and the second top surface may be an inclined surface inclined at the second angle θ₂ with respect to the top surface of the base layer BL. The connection surface of the second partition wall portion P2-W may correspond to an inner surface of the first partition wall layer L1.

In the second partition wall layer L2, a portion (also referred to herein as a sub-portion) of the second portion P2 and a portion (also referred to herein as a sub-portion) of the third portion P3 may define the tip portion TP. Referring to FIG. 5C, the second portion P2 of the second partition wall layer L2 may include a first sub-portion P2-1 and a second sub-portion P2-2. In an embodiment, the first sub-portion P2-1 is in contact with the second partition wall portion P2-W of the first partition wall layer L1, and the second sub-portion P2-2 protrudes from an inner surface of the second partition wall portion P2-W. The second sub-portion P2-2 may not be in contact with the second partition wall portion P2-W. The second sub-portion P2-2 may correspond to the first tip portion of the tip portion TP described herein.

The second partition wall layer L2 may have an inner surface that protrudes from the inner surface of the first partition wall layer L1. A portion of the inner surface of the first partition wall layer L1 may overlap the tip portion TP on a cross section. At least a portion of the inner surface of the first partition wall layer L1 may overlap the tip portion TP when viewed in a fourth direction DR4 perpendicular to the third direction DR3. For example, when viewed in the fourth direction DR4, the portion of the inner surface of the first partition wall layer L1 may overlap the tip portion TP, and the other portion may not overlap the tip portion TP.

The portion of the inner surface of the first partition wall layer L1, which overlaps the tip portion TP, may be covered by the tip portion TP and may not be exposed when viewed in the fourth direction DR4. In addition, the portion of the inner surface of the first partition wall layer L1, which does not overlap the tip portion TP, may be exposed by the tip portion TP when viewed in the fourth direction DR4. However, embodiments of the present disclosure are not limited thereto, and the entire area of the inner surface of the first partition wall layer L1 may overlap the tip portion TP when viewed in the fourth direction DR4. In this case, the entirety of the inner surface of the first partition wall layer L1 may be covered such that the entirety of the inner surface of the first partition wall layer L1 is not exposed by the tip portion TP when viewed in the fourth direction DR4. STOP

The length of the tip portion TP may be in a range of about 0.6 μm to about 1.5 μm. Example embodiments in which the length of the tip portion TP satisfies the range may prevent step coverage or the like. For example, in some cases, step coverage or the like may be formed as an organic layer deposited onto the inner surface of the first partition wall layer L1 along the bottom surface of the tip portion TP during forming of the emission pattern EP. Accordingly, for example, water vapor transmission through the step coverage may be prevented, securing reliability of the display device. In the present disclosure, the length of the tip portion TP may mean a sum of a first length d₁ of the third portion P3 of the second partition wall layer L2 and a second length d₂ of the second sub-portion P2-2 of the second portion P2 of the second partition wall layer L2.

In an embodiment, the length (d₁+d₂) of the tip portion TP may be represented by Equation 1 below. The length (d₁+d₂) of the tip portion TP, which is defined by Equation 1 below, may be about 0.6 μm to about 1.5 μm.

$$Length of tip portion = a + ( b / cos {θ}_{2} ) \qquad [ Equation 1 ]$$

In Equation 1, a represents the length d₁ of the bottom surface of the third portion P3.

In Equation 1, b represents a length measured from one end of the second sub-portion P2-2, which is adjacent to the third portion P3, to the other end of the second sub-portion P2-2, which is spaced part from the third portion P3, in a direction in which the third portion P3 extends. That is, b means a distance da between a first point PT1 and a second point PT2, in which the first point PT1 is defined as a first point at which the bottom surface of the second portion P2 is connected to the bottom surface of the third portion P3. The second point PT2 is defined as a second point at which a first virtual line IL1 extending in a direction perpendicular to the one direction, from a point at which the bottom surface of the second portion P2 is in contact with the inner surface of the first partition wall layer L1, meets a second virtual line IL2 extending from the first point PT1 in a direction parallel to the one direction.

In Equation 1, θ₂ represents the second angle.

Referring to FIG. 5C, the first virtual line IL1 may be defined as extending in a direction perpendicular to the direction in which the third portion P3 extends, from the point at which the bottom surface of the second portion P2 is in contact with the inner surface of the first partition wall layer L1. For example, the first virtual line IL1 may be a straight line extending in the third direction DR3 perpendicular to one direction DR4 parallel to the top surface of the base layer BL, from the point at which the bottom surface of the second portion P2 is in contact with the inner surface of the first partition wall layer L1. In addition, the second virtual line IL2 may be defined which extends in the direction in which the third portion P3 extends, from the first point PT1 at which the bottom surface of the second portion P2 is connected to the bottom surface of the third portion P3. For example, the second virtual line IL2 may be a straight line extending in the one direction DR4 parallel to the top surface of the base layer BL. Here, the bottom surface of the second sub-portion P2-2 of the second portion P2, the first virtual line IL1, and the second virtual line IL2 may be connected to each other to constitute a right-angled triangle. An angle formed between the bottom surface of the second sub-portion P2-2 of the second portion P2 and the second virtual line IL2 may be the second angle θ₂. The second length d₂ of the second sub-portion P2-2 may be b/cos θ₂. Thus, the length (d₁+d₂) of a portion protruding by the tip portion TP may be a sum of the first length d₁ and the second length d₂ corresponding to b/cos θₐ.

When the tip portion does not include the bending portion and includes the flat portion extending in one direction (e.g., includes only the flat portion extending in one direction rather than including the flat portion and the bending portion), step coverage may occur in which an organic layer is deposited from the bottom surface of the tip portion along the recessed inner side surface of the partition wall during depositing of the emission pattern in the partition wall opening portion. The step coverage may serve as a transmission path for foreign matters such as, for example, moisture or oxygen, and may cause a defect such as, for example, pixel shrinkage. In order to prevent the step coverage formation, aspects of the present disclosure described herein support a method of increasing the length of the tip portion in the given area of the emission area, a method of adjusting a deposition incident angle of an organic matter, or the like. However, in some cases, there may be a limit to increasing the length of the tip portion in the given area of the emission area, and even though the deposition incident angle is adjusted, it may be difficult to completely control the step coverage formation.

In the display panel according to an embodiment supported by aspects of the present disclosure, as the tip portion includes the first portion inclined at a predetermined angle, a length per unit area of the tip portion may be provided to be greater than a length per unit area of an existing tip portion such that the step coverage in which an organic matter is deposited onto the bottom surface of the tip portion is prevented. In some aspects, even when the deposition incident angle of an organic matter is not adjusted, the bottom surface of the tip portion, which corresponds to the first portion, may be blocked by the first portion during the depositing of the emission pattern such that the step coverage caused by the deposition of the organic matter is not formed. For example, even when the deposition incident angle is about 0°, a portion of the bottom surface of the tip portion may be blocked by the first portion to prevent the organic matter from being deposited onto a portion of the inner side surface of the partition wall along the tip portion. That is, for example, even when the organic matter is introduced from one end of the tip portion, which is adjacent to a center of the emission area PXA, in a direction parallel to the top surface of the base layer BL, the bottom surface of the tip portion, which corresponds to the first tip portion, may be blocked by the first portion such that the organic matter is prevented from being deposited onto a portion of the inner side surface of the partition wall along the tip portion. Accordingly, a defect such as, for example, pixel shrinkage likely to occur by the step coverage of the tip portion, may be prevented. In some aspects, the step coverage formation may be suppressed even without an additional means for adjusting the incident angle, thereby reducing the manufacturing costs associated with the display panel and simplifying the process and also reducing a defect rate during the manufacture.

Referring to FIG. 5A again, the first partition wall layer L1 may include a conductive material. The conductive material may include a metal, a transparent conductive oxide (TCO), or a combination of a metal and a transparent conductive oxide (TCO). For example, the metal may include gold (Au), silver (Ag), aluminum (Al), magnesium (Mg), lithium (Li), molybdenum (Mo), titanium (Ti), copper (Cu), or an alloy of any of gold (Au), silver (Ag), aluminum (Al), magnesium (Mg), lithium (Li), molybdenum (Mo), titanium (Ti), or copper (Cu). The transparent conductive oxide may include an indium tin oxide (ITO), an indium zinc oxide (IZO), a zinc oxide, an indium oxide, an indium gallium oxide, an indium gallium zinc oxide (IGZO), or an aluminum zinc oxide.

The second partition wall layer L2 may be disposed on the first partition wall layer L1. The second partition wall layer L2 may be disposed directly on the first partition wall layer L1. The second partition wall layer L2 may define the tip portion provided on the partition wall PW. The top surface of the second partition wall layer L2 may constitute the uppermost surface of the partition wall PW, and may define the top surface of the tip portion provided on the partition wall PW.

The second partition wall layer L2 may include a material having lower electrical conductivity but higher strength than the material of the first partition wall layer L1. The second partition wall layer L2 may include a material having a high Young's modulus of, for example, about 300 GPa or greater. For cases in which the second partition wall layer L2 includes a material having a high Young's modulus described herein, deformation of the second partition wall layer L2 may be reduced. As the deformation of the second partition wall layer L2 constituting the uppermost surface of the partition wall PW is reduced, robustness of the undercut shape of the partition wall PW may increase. Accordingly, a shape in which the tip portion of the partition wall PW sags may be reduced or removed, and a shape in which the tip portion blocks the inner side surface of the partition wall PW, which is in contact with the cathode CE, may be reduced or removed.

In an embodiment, the second partition wall layer L2 may include a second metal or a silicon-based compound.

In an embodiment, the second partition wall layer L2 may include a second metal. The second metal included in the second partition wall layer L2 may include gold (Au), silver (Ag), aluminum (Al), magnesium (Mg), lithium (Li), molybdenum (Mo), titanium (Ti), copper (Cu), or an alloy of gold (Au), silver (Ag), aluminum (Al), magnesium (Mg), lithium (Li), molybdenum (Mo), titanium (Ti), or copper (Cu). The second partition wall layer L2 may include a metal material different from the metal material of the first partition wall layer L1. The second partition wall layer L2 may include, for example, titanium (Ti). The second partition wall layer L2 may have a thickness of about 400 angstroms to about 800 angstroms.

In an embodiment, the second partition wall layer L2 may not include a metal material, unlike the first partition wall layer L1 including a metal material. That is, for example, the second partition wall layer L2 may include a non-metal material. The second partition wall layer L2 may include a silicon-based compound. The second partition wall layer L2 may include at least one of a silicon oxide (SiOₓ), a silicon nitride (SiNₓ), or a silicon oxynitride (SiOₓN_{y}). The second partition wall layer L2 may include, for example, a silicon oxide (SiOₓ). The second partition wall layer L2 is a component that is not in contact with the cathode CE, unlike the first partition wall layer L1 which is in contact with the cathode CE. The second partition wall layer L2 has the tip portion which confines the cathode CE to the emission area PXA, and the second partition wall layer L2 thus may also include the silicon-based compound that is an insulation material.

The emission pattern EP may be disposed on the anode AE. The emission pattern EP may include an emission layer including a light emitting material. The emission pattern EP may further include a hole injection layer HIL and a hole transport layer HTL, which are disposed between the anode AE and the emission layer. The emission pattern EP may further include an electron transport layer ETL and an electron transport layer EIL, which are disposed on the emission layer. The emission pattern EP may be referred to as an “organic layer” or an “intermediate layer”.

The emission pattern EP may be patterned by the tip portion TP defined in the partition wall PW. The emission pattern EP may be disposed inside the sacrificial opening portion OP-S, the emission opening portion OP-E, and the partition wall opening portion OP-P. The emission pattern EP may cover a portion of the top surface of the pixel defining film PDL, which is exposed from the partition wall opening portion OP-P.

The cathode CE may be disposed on the emission pattern EP. The cathode CE may be patterned by the tip portion TP defined in the partition wall PW. The cathode CE may be in contact with the first inner side surface S-L1 of the first partition wall layer L1. The cathode CE may have conductivity. The cathode CE may be formed of various materials such as, for example, a metal, a transparent conductive oxide (TCO), or a conductive polymeric material, such that the cathode CE is capable of exhibiting conductivity.

The partition wall PW may receive a bias voltage. As the cathode CE is in direct contact with the partition wall PW, the cathode CE and the partition wall PW may be electrically connected to each other, and receive the bias voltage.

As an example, FIG. 5A illustrates a state in which the emission pattern EP is not in contact with the first inner side surface S1-P of the first partition wall layer L1. However, embodiments supported by the present disclosure are not limited thereto, and a portion of the emission pattern EP may be in contact with the first inner side surface S1-P.

According to an embodiment supported by aspects of the present disclosure, the display panel DP may further include a capping pattern CP. The capping pattern CP may be disposed in the partition wall opening portion OP-P and disposed on the cathode CE. The capping pattern CP may be patterned by the tip portion TP provided on the partition wall PW. The capping pattern CP may include at least one of an inorganic layer or an organic layer. The capping pattern CP may protect the light emitting element ED disposed therebelow.

The dummy patterns DMP may be disposed on the partition wall PW. The dummy patterns DMP may include a first dummy pattern D1, a second dummy pattern D2, and a third dummy pattern D3. The first to third dummy patterns D1, D2 and D3 may be stacked in sequence on the top surface of the second partition wall layer L2 of the partition wall PW in the third direction DR3.

The first dummy pattern D1 may include an organic material. For example, the first dummy pattern D1 may include the same material as the emission pattern EP. The first dummy pattern D1 may be formed together with the emission pattern EP at the same time through one process, and then separated from the emission pattern EP by the undercut shape of the partition wall PW.

The second dummy pattern D2 may include a conductive material. For example, the second dummy pattern D2 may include the same material as the cathode CE. The second dummy pattern D2 may be formed together with the cathode CE at the same time through one process, and the second dummy pattern D2 may then be separated from the cathode CE by the undercut shape of the partition wall PW.

The third dummy pattern D3 may include at least one of an inorganic layer or an organic layer. The third dummy pattern D3 may include the same material as the capping pattern CP. The third dummy pattern D3 may be formed together with the capping pattern CP at the same time through one process, and the third dummy pattern D3 may then be separated from the capping pattern CP by the undercut shape of the partition wall PW.

A dummy opening portion OP-D may be defined in the dummy patterns DMP. The dummy opening portion OP-D may correspond to the emission opening portion OP-E. The dummy opening portion OP-D may be defined by respective inner side surfaces of the first to third dummy patterns D1, D2 and D3. In an embodiment, the respective inner side surfaces of the first to third dummy patterns D1, D2 and D3 may be substantially aligned and may define an integral opening space of the dummy opening portion OP-D. Each of the first to third dummy patterns D1, D2 and D3 may have a closed line shape surrounding a corresponding emission area PXA on a plane.

As an example, FIG. 5A illustrates a state in which the respective inner side surfaces of the first to third dummy patterns D1, D2 and D3 are aligned with the second inner side surface S-L2 of the second partition wall layer L2. However, embodiments supported by the present disclosure are not limited thereto, and the inner side surfaces of the first to third dummy patterns D1, D2 and D3 may cover at least a portion of the second inner side surface S2-P of the second partition wall layer L2.

The encapsulation layer TFE may be disposed on the display element layer D-OL. The encapsulation layer TFE may include a lower inorganic encapsulation pattern LIL, an organic encapsulation film OL, and an upper inorganic encapsulation film UIL.

The lower inorganic encapsulation pattern LIL may correspond to the emission opening portion OP-E. The lower inorganic encapsulation pattern LIL may cover the light emitting element ED and the dummy patterns DMP, and a portion of the lower inorganic encapsulation pattern LIL may be disposed inside the partition wall opening portion OP-P and be in contact with the partition wall PW.

The organic encapsulation film OL may cover the lower inorganic encapsulation pattern LIL, and provide a flat top surface. The upper inorganic encapsulation film UIL may be disposed on the organic encapsulation film OL.

The lower inorganic encapsulation pattern LIL and the upper inorganic encapsulation film UIL may protect the display element layer D-OL from moisture/oxygen, and the organic encapsulation film OL may protect the display element layer D-OL from a foreign matter such as, for example, dust particles.

FIG. 5D is a cross-sectional view of the display panel according to an embodiment supported by aspects of the present disclosure taken along line II-II′ in FIG. 4. FIG. 5D is an enlarged view illustrating a first emission area PXA-R, a second emission area PXA-G, and a third emission area PXA-B. The same/similar description of the one emission area PXA in FIGS. 5A to 5C may apply to each of the first to third emission areas PXA-R, PXA-G and PXA-B.

Referring to FIG. 5D, the display panel DP according to one or more embodiments may include a base layer BL, a circuit element layer D-CL, a fifth insulation layer 50, a display element layer D-OL, and an encapsulation layer TFE. The display element layer D-OL may include light emitting elements ED1, ED2 and ED3, sacrificial patterns SP1, SP2 and SP3, a pixel defining film PDL, a partition wall PW, and dummy patterns DMP.

Light emitting elements ED1, ED2 and ED3 may include a first light emitting element ED1, a second light emitting element ED2, and a third light emitting element ED3.

The first light emitting element ED1 may include a first anode AE1 (or (1-1)-th electrode), a first emission pattern EP1, and a first cathode CE1 (or (2-1)-th electrode). The second light emitting element ED2 may include a second anode AE2 (or (1-2)-th electrode), a second emission pattern EP2, and a second cathode CE2 (or (2-2)-th electrode). The third light emitting element ED3 may include a third anode AE3 (or (1-3)-th electrode), a third emission pattern EP3, and a third cathode CE3 (or (2-3)-th electrode). The first to third anodes AE1, AE2 and AE3 may be provided as a plurality of patterns. In an embodiment, the first emission pattern EP1 may provide red light, the second emission pattern EP2 may provide green light, and the third emission pattern EP3 may provide blue light.

In the example embodiment, first to third emission opening portions OP1-E, OP2-E and OP3-E may be defined in the pixel defining film PDL.

The first emission opening portion OP1-E may expose at least a portion of the first anode AE1. The first emission area PXA-R may be defined as an area, which is exposed by the first emission opening portion OP1-E, of a top surface of the first anode AE1. The second emission opening portion OP2-E may expose at least a portion of the second anode AE2. The second emission area PXA-G may be defined as an area, which is exposed by the second emission opening portion OP2-E, of a top surface of the second anode AE2. The third emission opening portion OP3-E may expose at least a portion of the third anode AE3. The third emission area PXA-B may be defined as an area, which is exposed by the third emission opening portion OP3-E, of a top surface of the third anode AE3.

In the example embodiment, the sacrificial patterns SP1, SP2 and SP3 may include a first sacrificial pattern SP1, a second sacrificial pattern SP2, and a third sacrificial pattern SP3. The first to third sacrificial patterns SP1, SP2 and SP3 may be disposed on top surfaces on the first to third anodes AE1, AE2 and AE3, respectively.

First to third sacrificial opening portions OP1-S, OP2-S and OP3-S overlapping the first to third emission opening portions OP1-E, OP2-E and OP3-E may be defined in the first to third sacrificial patterns SP1, SP2 and SP3, respectively.

In the example embodiment, first to third partition wall opening portions OP1-P, OP2-P and OP3-P overlapping the first to third emission opening portions OP1-E, OP2-E and OP3-E, respectively, may be defined in the partition wall PW. The first emission pattern EP1 and the first cathode CE1 may be disposed in the first partition wall opening portion OP1-P, the second light emitting element ED2 and the second cathode CE2 may be disposed in the second partition wall opening portion OP2-P, and the third light emitting element ED3 and the third cathode CE3 may be disposed in the third partition wall opening portion OP3-P. Each of the first to third cathodes CE1, CE2 and CE3 may be in contact with the first inner side surfaces S1-P (see FIG. 5A) of the first partition wall layer L1.

In the example embodiment, the first to third cathodes CE1, CE2 and CE3 may be physically separated by the second partition wall layer L2, which defines a tip portion, and defined in the emission opening portions OP1-E, OP2-E and OP3-E, respectively, and may each be in contact with the first partition wall layer L1 and thus electrically connected to each other to receive a common voltage. The first partition wall layer L1 may have relatively high electrical conductivity and large thickness compared to the second partition wall layer L2, and thus reduce contact resistance with the first to third cathodes CE1, CE2 and CE3. Accordingly, a common cathode voltage may be uniformly supplied to the emission areas PXA-R, PXA-G and PXA-B.

According to an embodiment supported by aspects of the present disclosure, the plurality of emission patterns EP1, EP2 and EP3 may be patterned and deposited into pixel units by the tip portion defined in the partition wall PW. That is, the first emission patterns EP1 may be formed in common using an open mask, but easily separated into the pixel units by the partition wall PW.

In contrast, according to some other approaches, a fine metal mask (FMM) is used to pattern the first emission patterns EP1, and a support spacer protruding from the partition wall is be provided to support the fine metal mask. As the fine metal mask is spaced a height of the partition wall and the spacer from a base surface that is subjected to patterning, achievement of high resolution may be restricted. Moreover, as the fine metal mask is in contact with the spacer, a foreign matter may remain on the spacer or the spacer may be damaged due to stabbing of the fine metal mask after a process of patterning the first emission patterns EP1. Accordingly, such other approaches may result in a defective display panel.

According to one or more embodiments, as the partition wall PW is included, physical separation between the light emitting elements ED1, ED2 and ED3 may be easily achieved. Accordingly, drive errors or current leakage between adjacent emission areas PXA-R, PXA-G and PXA-B may be prevented, and the light emitting elements ED1, ED2 and ED3 may be each driven independently of each other.

Particularly as the plurality of first emission patterns EP1 are patterned without a mask in contact with inner components in the display area DA (see FIG. 2), a defect rate may be reduced such that the display panel DP with improved process reliability is provided. As the patterning is enabled even when a separate support spacer protruding from the partition wall PW is not provided, the respective areas of the emission areas PXA-R, PXA-G and PXA-B may be miniaturized to provide the display panel DP easily implemented at high resolution.

In addition, as the techniques described herein support omitting the manufacture of a mask having a large area from the manufacture of the display panel DP having a large area, process costs may be reduced, and the display panel DP may not be affected by a defect likely to occur in the mask having a large area. Accordingly, the display panel DP with improved process reliability may be provided.

In the example embodiment, capping patterns CP1, CP2 and CP3 may include a first capping pattern CP1, a second capping pattern CP2, and a third capping pattern CP3. The first to third capping patterns CP1, CP2 and CP3 may be disposed on the first to third cathode CE1, CE2 and CE3, respectively and be disposed within the first to third partition wall opening portions OP1-P, OP2-P and OP3-P, respectively.

In the example embodiment, the dummy patterns DMP may include a plurality of first dummy patterns D1, a plurality of second dummy patterns D2, and a plurality of third dummy patterns D3.

The first dummy patterns D1 may include (1-1)-th to (1-3)-th dummy patterns D11, D12 and D13 surrounding the first to third emission areas PXA-R, PXA-G and PXA-B, respectively, on a plane. The (1-1)-th to (1-3)-th dummy patterns D11, D12 and D13 may include the same materials as the first to third emission patterns EP1, EP2 and EP3, respectively, and be formed through the same processes as the first to third emission patterns EP1, EP2 and EP3, respectively.

The second dummy patterns D2 may include (2-1)-th to (2-3)-th dummy patterns D21, D22 and D23 surrounding the first to third emission areas PXA-R, PXA-G and PXA-B, respectively, on a plane. The (2-1)-th to (2-3)-th dummy patterns D21, D22 and D23 may include the same materials as the first to third cathodes CE1, CE2 and CE3, respectively, and be formed through the same processes as the first to third cathodes CE1, CE2 and CE3, respectively.

The third dummy patterns D3 may include (3-1)-th to (3-3)-th dummy patterns D31, D32 and D33 surrounding the first to third emission areas PXA-R, PXA-G and PXA-B, respectively, on a plane. The (3-1)-th to (3-3)-th dummy patterns D31, D32 and D33 may include the same materials as the first to third capping patterns CP1, CP2 and CP3, respectively, and be formed through the same processes as the first to third capping patterns CP1, CP2 and CP3, respectively.

First to third dummy opening portions OP1-D, OP2-D and OP3-D corresponding to the first to third emission opening portions OP1-E, OP2-E and OP3-E may be defined in the dummy patterns DMP, respectively. Each of the first to third dummy opening portions OP1-D, OP2-D and OP3-D may include first to third regions AA1, AA2 and AA3 (see FIG. 91) that are arranged in sequence in the third direction DR3. The first dummy opening portion OP1-D may be defined by inner side surfaces of the (1-1)-th, (2-1)-th, and (3-1)-th dummy patterns D11, D21 and D31, the second dummy opening portion OP2-D may be defined by inner side surfaces of the (1-2)-th, (2-2)-th, and (3-2)-th dummy patterns D12, D22 and D32, and the third dummy opening portion OP3-D may be defined by inner side surfaces of the (1-3)-th, (2-3)-th, and (3-3)-th dummy patterns D13, D23 and D33.

The encapsulation layer TFE may include lower inorganic encapsulation patterns LIL1, LIL2 and LIL3, an organic encapsulation film OL, and an upper inorganic encapsulation film UIL. In the example embodiment, the lower inorganic encapsulation patterns LIL1, LIL2 and LIL3 may include a first lower inorganic encapsulation pattern LIL1, a second lower inorganic encapsulation pattern LIL2, and a third lower inorganic encapsulation pattern LIL3. The first to third lower inorganic encapsulation patterns LIL1, LIL2 and LIL3 may overlap the first to third emission opening portions OP1-E, OP2-E and OP3-E, respectively.

The first lower inorganic encapsulation pattern LIL1 may cover the first light emitting element ED1 and the (1-1)-th, (2-1)-th, and (3-1)-th dummy patterns D11, D21 and D31, and have a portion disposed inside the first partition wall opening portion OP1-P. The second lower inorganic encapsulation pattern LIL2 may cover the second light emitting element ED2 and the (1-2)-th, (2-2)-th, and (3-2)-th dummy patterns D12, D22 and D32, and have a portion disposed inside the second partition wall opening portion OP2-P. The third lower inorganic encapsulation pattern LIL3 may cover the third light emitting element ED3 and the (1-3)-th, (2-3)-th, and (3-3)-th dummy patterns D13, D23 and D33, and have a portion disposed inside the third partition wall opening portion OP3-P. The first to third lower inorganic encapsulation patterns LIL1, LIL2 and LIL3 may be provided in the form of patterns spaced apart from each other.

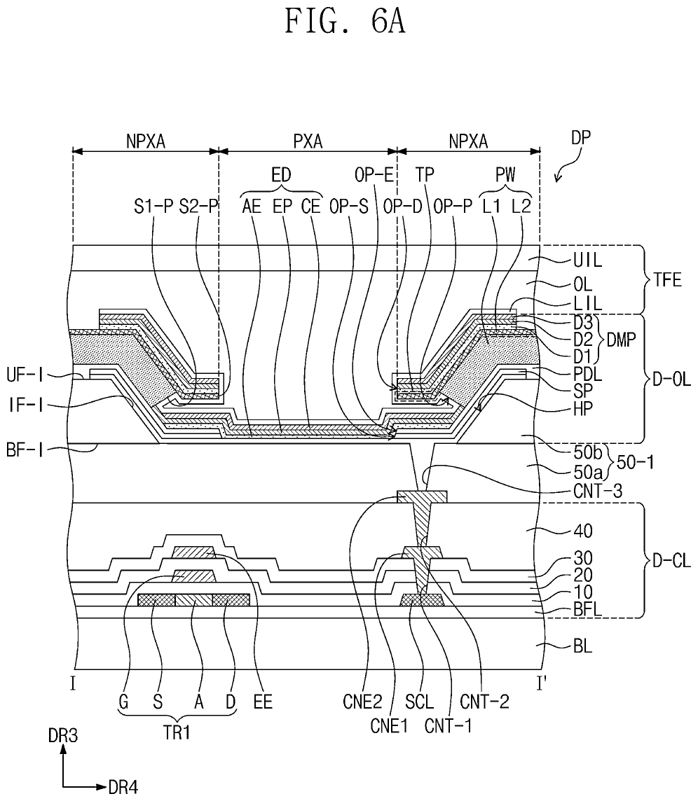

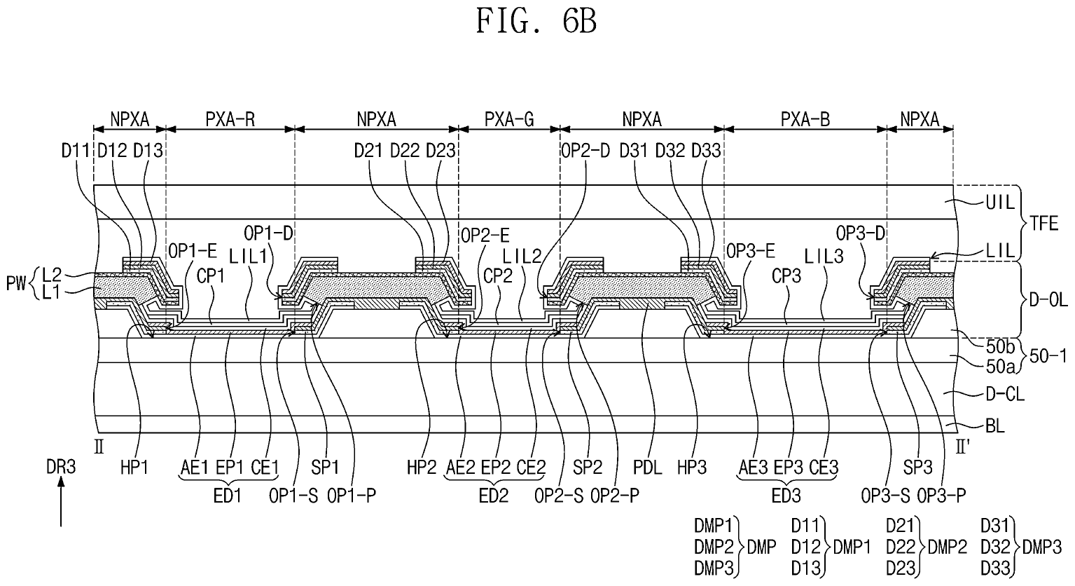

FIG. 6A is an enlarged cross-sectional view of a partial region of a display panel according to an embodiment supported by aspects of the present disclosure. FIG. 6B is a cross-sectional view of a display panel according to an embodiment supported by aspects of the present disclosure. FIG. 6B is a cross-sectional view of the display panel according to an embodiment supported by aspects of the present disclosure taken along line II-II′ in FIG. 4. Hereinafter, a display panel according to an embodiment supported by aspects of the present disclosure will be described with reference to FIGS. 6A and 6B. The same/similar components as/to those described with reference to FIGS. 5A to 5D are denoted as the same/similar reference numbers or symbols, and the detailed descriptions thereof are omitted.

Referring to FIGS. 6A and 6B, in a display panel DP according to an embodiment supported by aspects of the present disclosure, a fifth insulation layer 50-1 may include a plurality of films. In the example embodiment, the fifth insulation layer 50-1 may include a lower film 50a and an upper film 50b. The lower film 50a may be provided to be entirely flat, and the upper film 50b may be disposed on the lower film 50a and have an inner side surface IF-I defined by a portion that is penetrated. A portion of a top surface of the lower film 50a may be exposed by the inner side surface IF-I defined in the upper film 50b. The inner side surface IF-I of the upper film 50b and the top surface of the lower film 50a, which is exposed by the inner side surface IF-I, may define a groove HP of the fifth insulation layer 50-1. The groove HP may provide a space in which an anode AE and a sacrificial pattern SP may be disposed. The anode AE may be disposed on the top surface of the lower film 50a, which is exposed by the inner side surface IF-I, and the inner side surface IF-I.

Example aspects of methods and processes supported by aspects of the present disclosure are described herein. In the descriptions of the methods and processes herein, the operations may be performed in a different order than the order shown and/or described, or the operations may be performed in different orders or at different times. Certain operations may also be left out, one or more operations may be repeated, or other operations may be added.

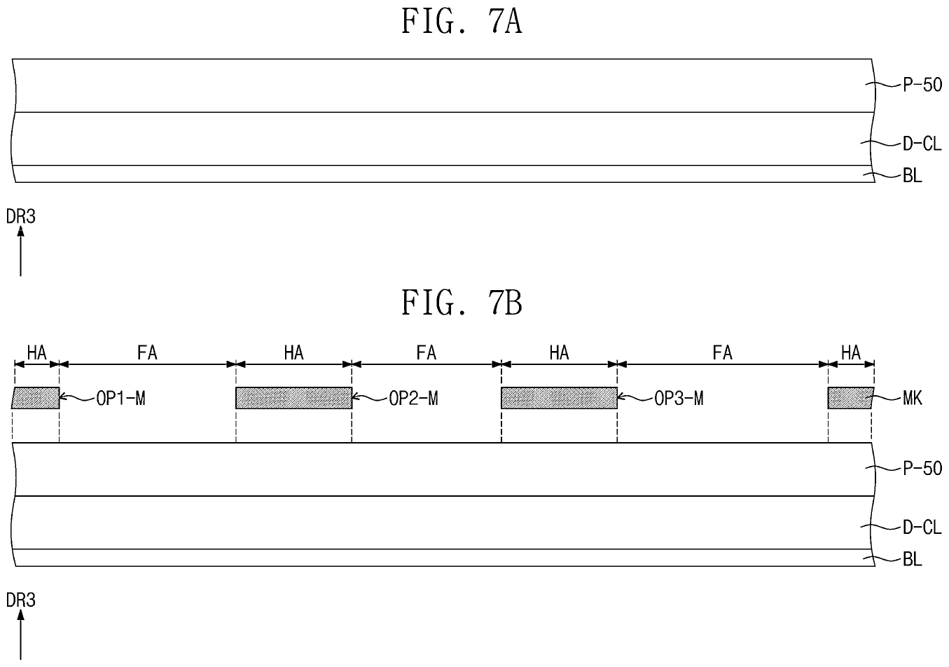

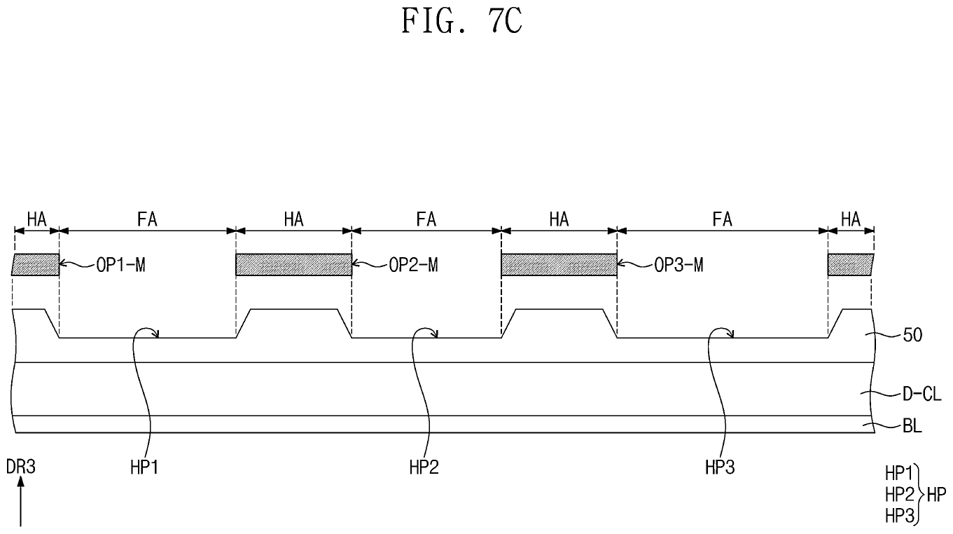

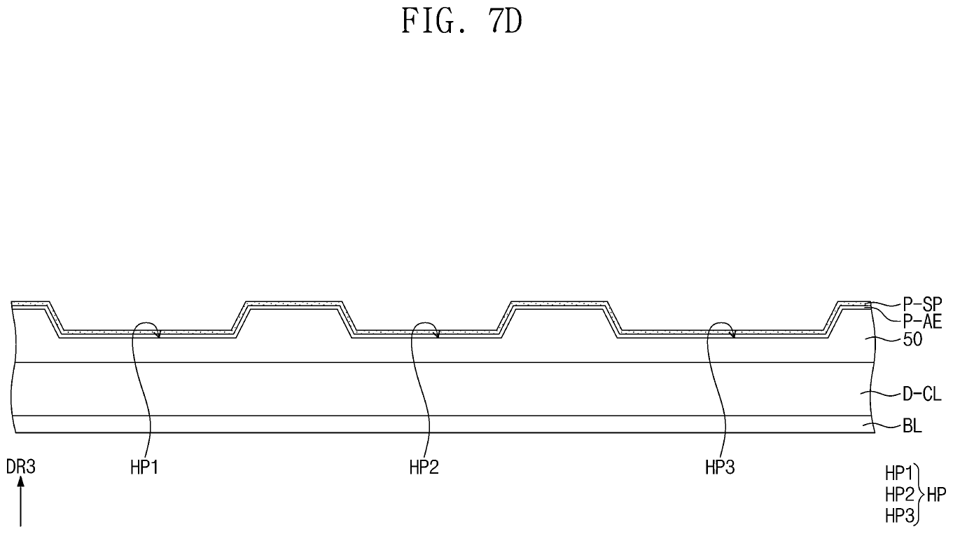

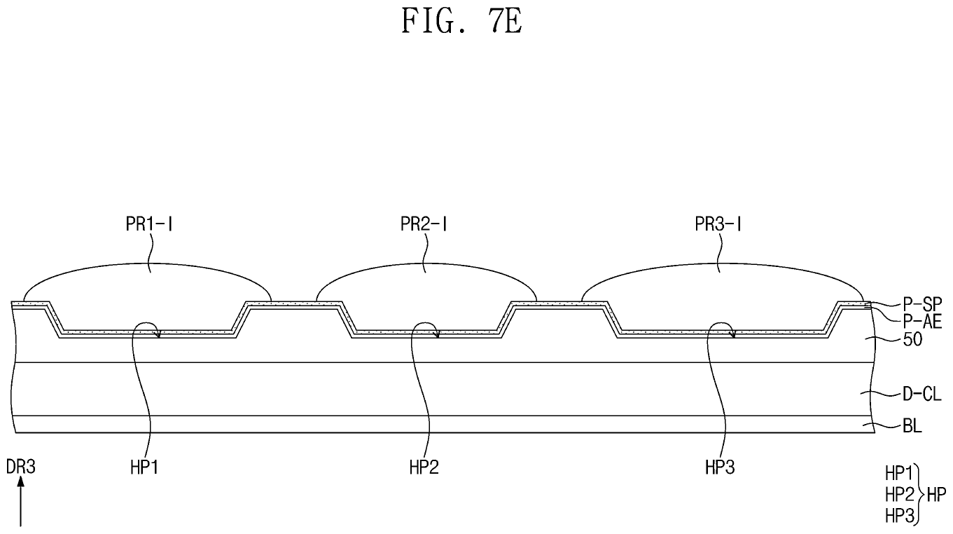

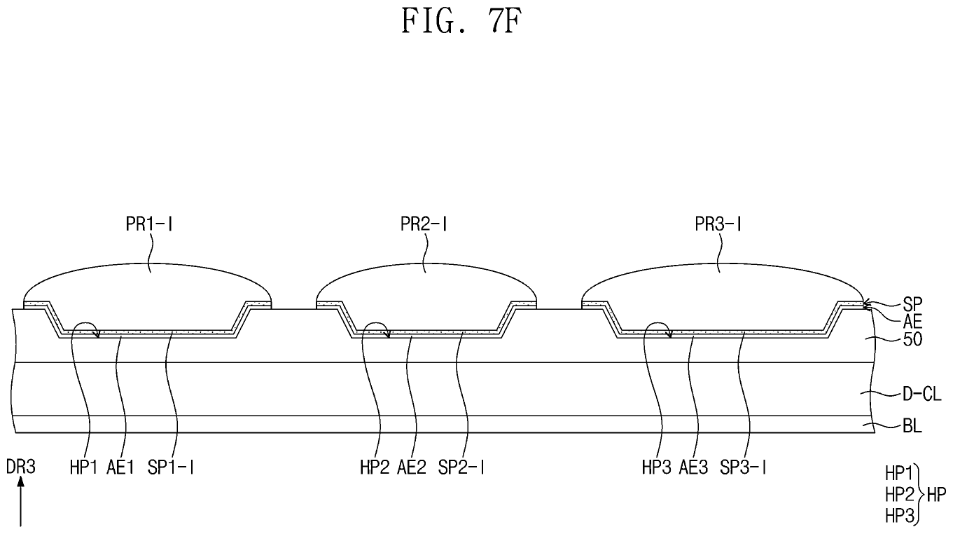

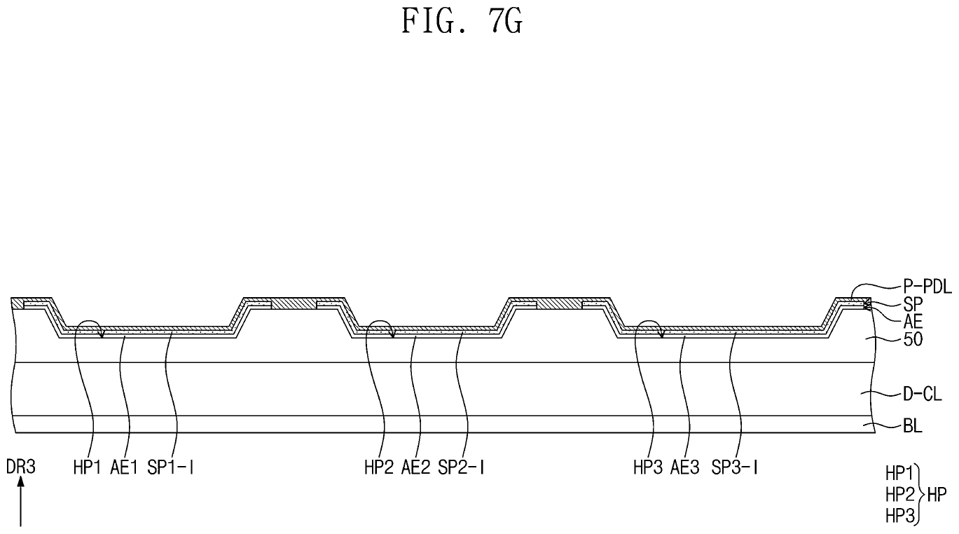

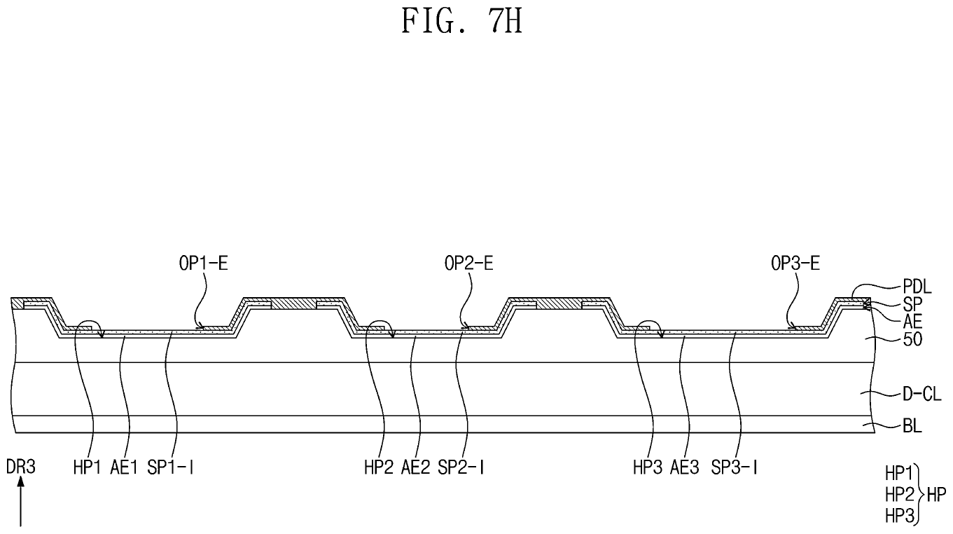

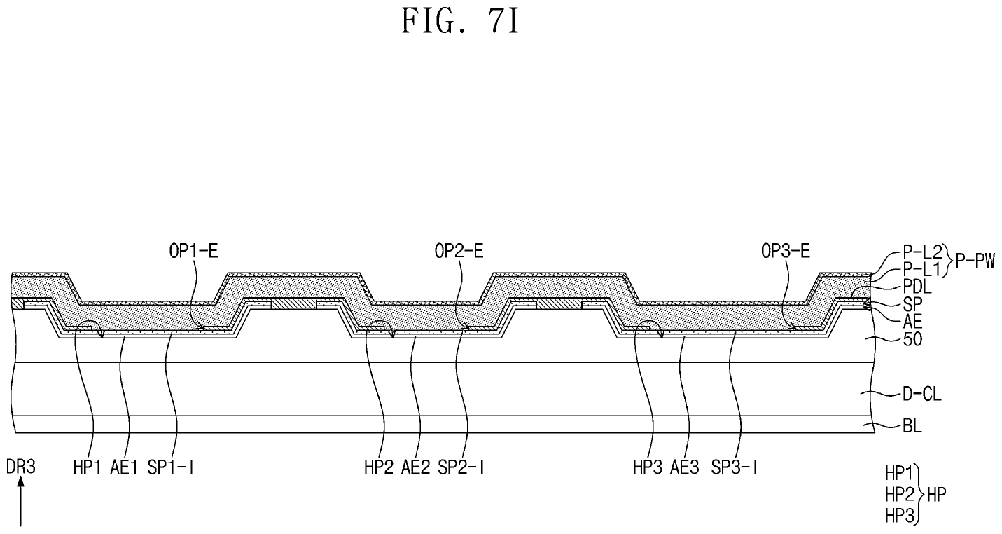

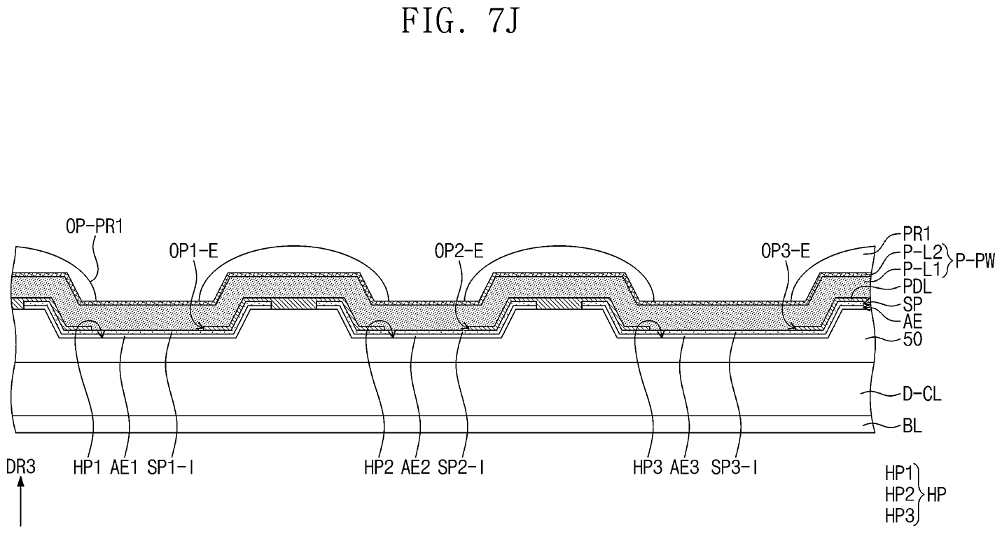

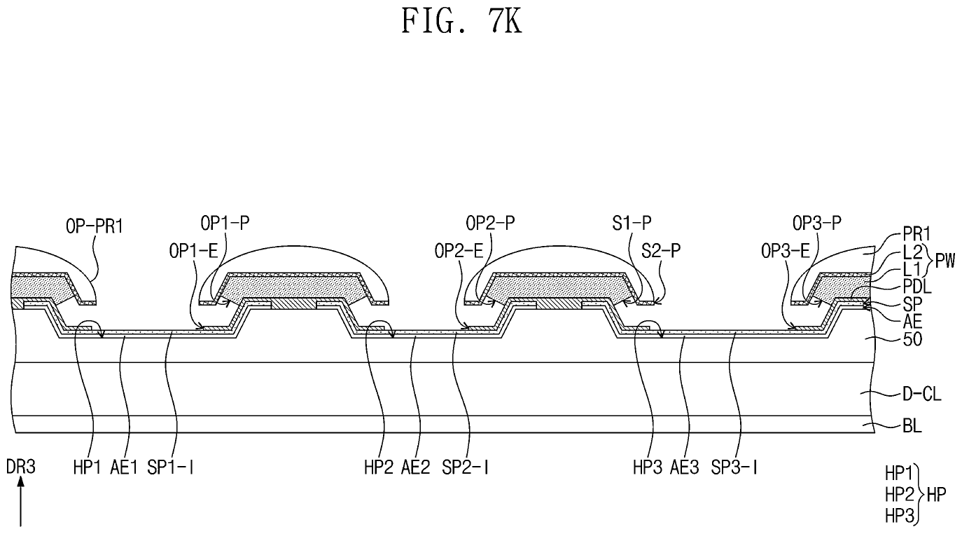

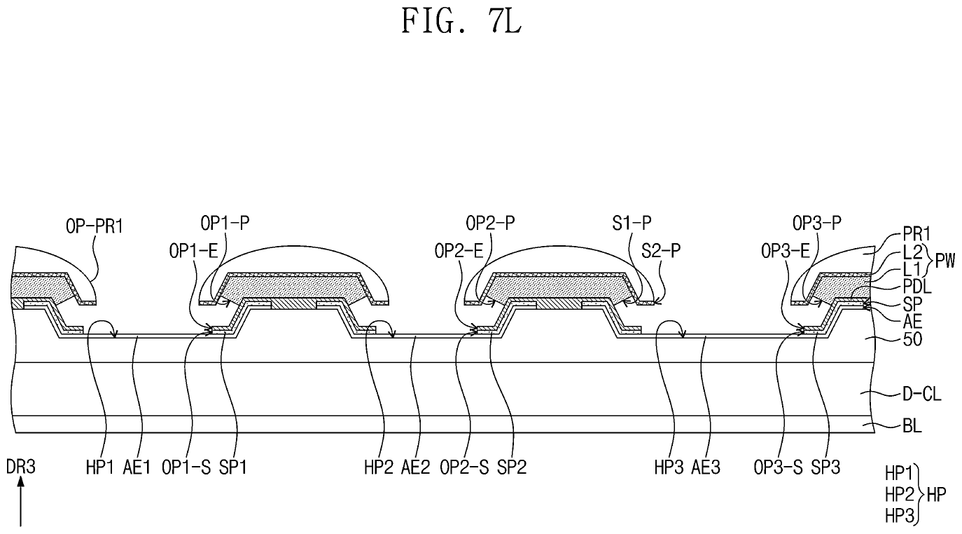

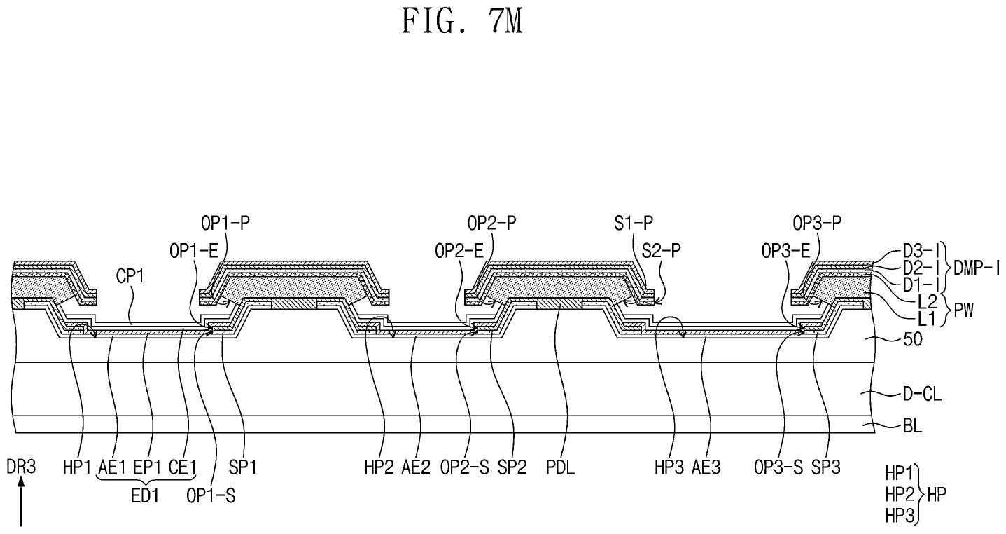

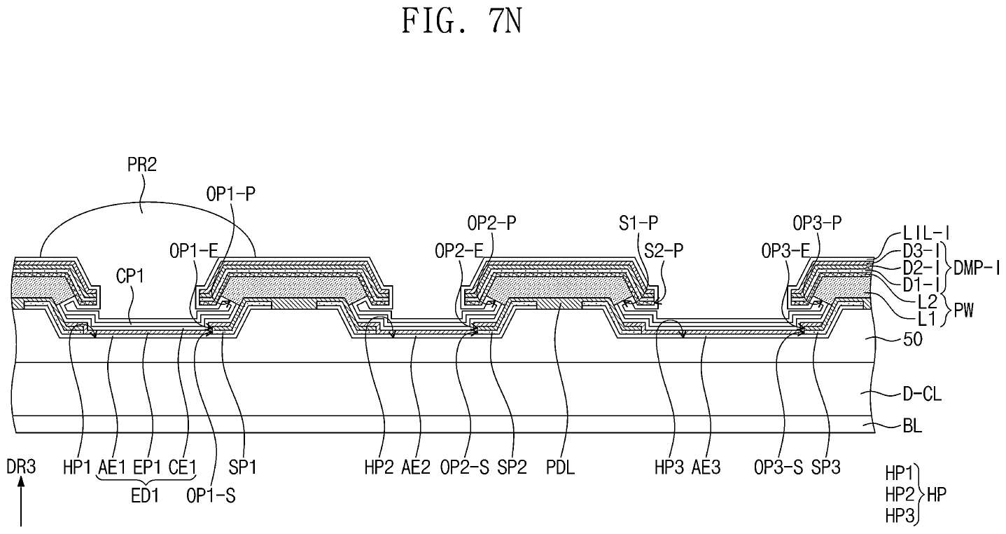

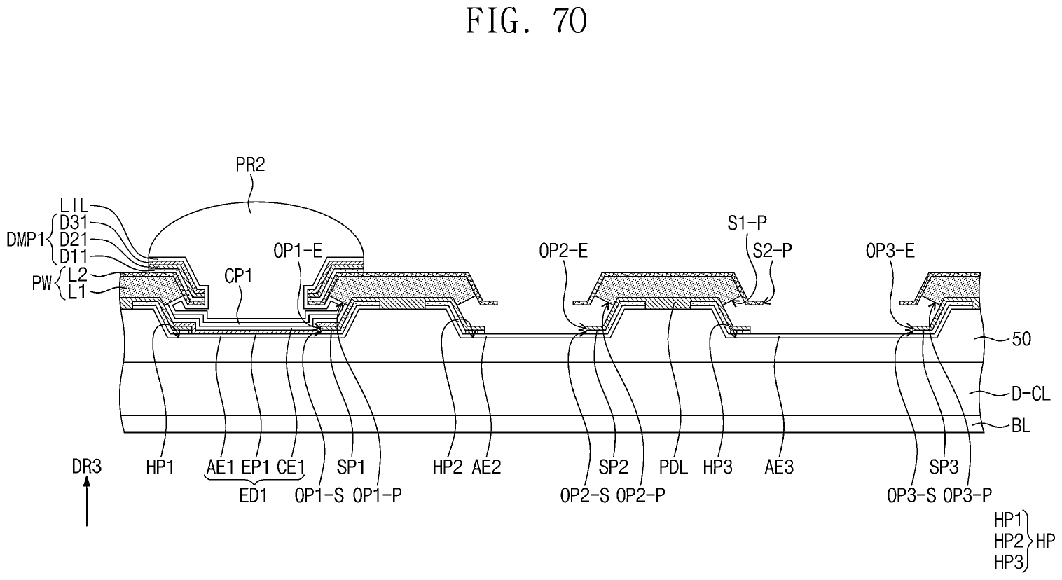

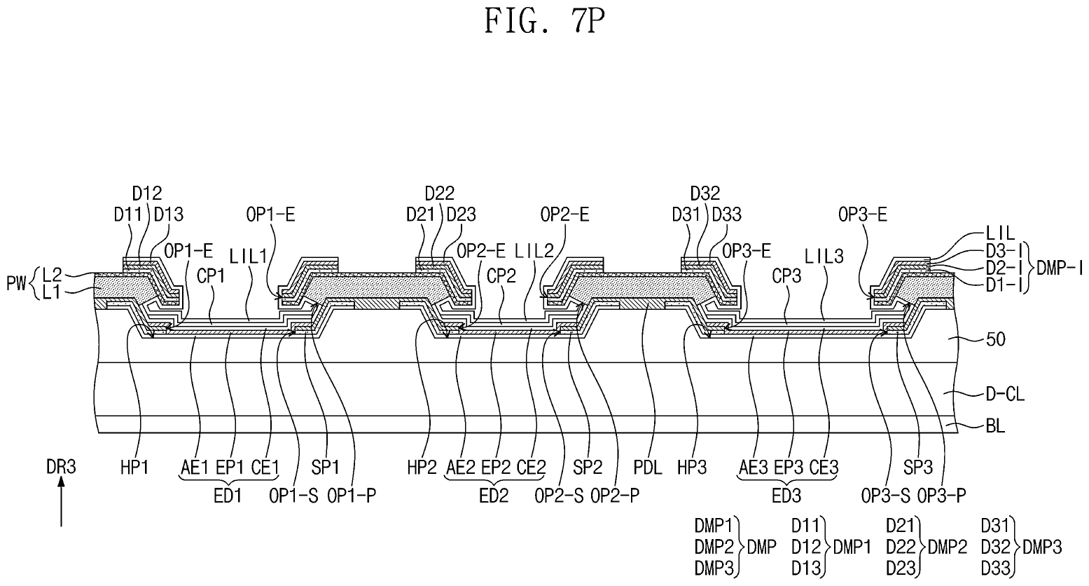

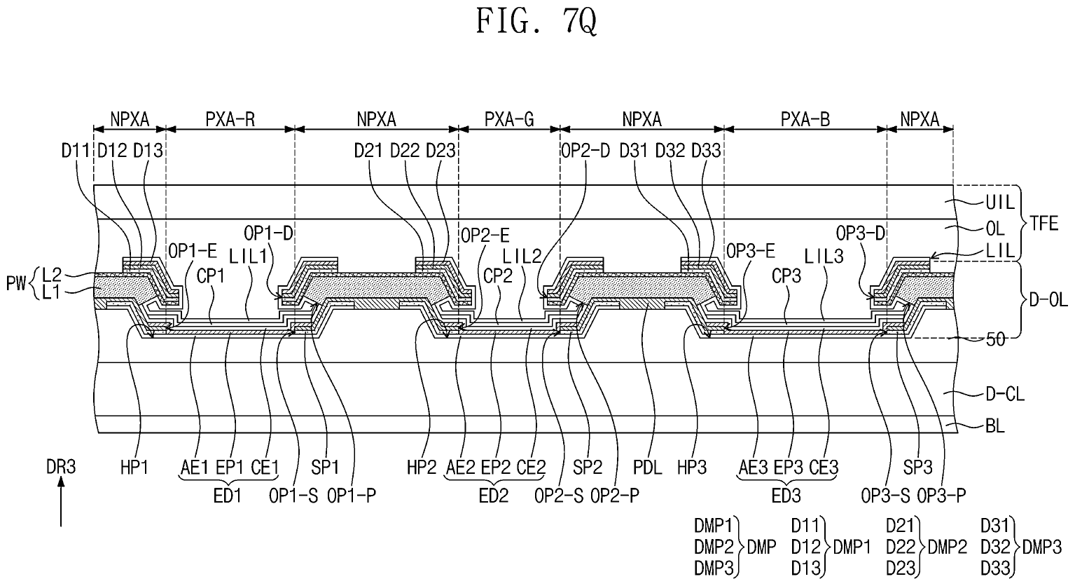

FIGS. 7A to 7Q are cross-sectional views illustrating some operations of a method for manufacturing a display panel according to an embodiment supported by aspects of the present disclosure. Hereinafter, the method for manufacturing a display panel according to an embodiment supported by aspects of the present disclosure will be described with reference to FIGS. 7A to 7Q. The same/similar components as/to those described herein are denoted as the same/similar reference numbers or symbols, and the detailed descriptions thereof are omitted.

The method for manufacturing the display panel according to an embodiment supported by aspects of the present disclosure may include preparing a base layer on which an emission area and a peripheral area adjacent to the emission area are defined. The method may include forming, on the base layer, an insulation layer in which a groove overlapping the emission area is defined. The method may include forming an anode in the groove defined in the insulation layer. The method may include forming, on the insulation layer, a pixel defining film in which an emission opening portion overlapping the anode is defined. The method may include forming, on the pixel defining film, a partition wall in which a partition wall opening portion overlapping the emission opening portion is defined. The method may include forming an emission pattern including at least a portion disposed in the emission opening portion, and forming a cathode including at least a portion disposed in the partition wall opening portion, wherein the cathode is in contact with an inner side surface of the partition wall, that defines the partition wall opening portion.

Referring to FIG. 7A, the method for manufacturing the display panel according to an embodiment supported by aspects of the present disclosure may include preparing a base layer BL. The method for manufacturing the display panel according to an embodiment supported by aspects of the present disclosure may further include forming a circuit element layer D-CL on the base layer BL.

The circuit element layer D-CL may be formed through a typical process for manufacture a circuit element by forming an insulation layer, a semiconductor layer, and a conductive layer through coating, deposition or the like, and then selectively patterning the insulation layer, the semiconductor layer, and the conductive layer through a photolithography process and an etching process to form a semiconductor pattern, a conductive pattern, signal lines, and the like. The anode AE may be formed on the circuit element layer D-CL. The anode AE may be formed using various methods such as, for example, a deposition process or a sputtering process.

Referring to FIGS. 7A to 7C, the method for manufacturing the display panel according to an embodiment supported by aspects of the present disclosure may include forming, on the base layer BL, an insulation layer 50 in which a groove HP is defined. The forming of the insulation layer 50 may include forming a preliminary insulation layer P-50 on the base layer BL, and patterning the preliminary insulation layer P-50.

The method may include forming preliminary insulation layer P-50 on the circuit element layer D-CL. The preliminary insulation layer P-50 may be formed on an insulation layer, for example, the fourth insulation layer 40 (see FIG. 5A), disposed on the uppermost side of the circuit element layer D-CL. The preliminary insulation layer P-50 may be formed using various methods such as, for example, coating or deposition.

Referring to FIGS. 7B and 7C, the method may include performing the patterning of the preliminary insulation layer P-50 after the forming of the preliminary insulation layer P-50. The patterning of the preliminary insulation layer P-50 may include generating and emitting light onto the preliminary insulation layer P-50 (e.g., exposing the preliminary insulation layer P-50 to the light) and developing the preliminary insulation layer P-50.

The method may include providing a mask MK on the preliminary insulation layer P-50 in order to pattern the preliminary insulation layer P-50. The mask MK may include a transmission part FA and a semi-transmission part HA. The method may include defining first to third mask opening portions OP1-M, OP2-M and OP3-M to correspond to the transmission part FA in the mask MK. The position of each of the transmission part FA and the semi-transmission part HA in the mask MK may be changed according to a pattern formed from the preliminary insulation layer P-50 by using the mask MK. The mask MK may be a half tone mask including regions having different light transmittances in the mask MK.

The transmission part FA may be a region through which light emitted on the mask MK is transmitted. The semi-transmission part HA may be a region having a lower light transmittance than the transmission part FA. The patterned shape of the preliminary insulation layer P-50 may be changed according to a level of light transmitted to the preliminary insulation layer P-50.

The method may include disposing the mask MK on the preliminary insulation layer P-50, and the method may include then supplying light to the preliminary insulation layer P-50 to perform an exposure process on the preliminary insulation layer P-50. Due to light, which passes through the transmission part FA of the mask MK, of the supplied light, a first amount of light per unit area may be supplied to a portion, which overlaps the transmission part FA, of the preliminary insulation layer P-50. In addition, due to light, which passes through the semi-transmission part HA of the mask MK, of the supplied light, a second amount of light per unit area may be supplied to a portion of the preliminary insulation layer P-50, where the portion overlaps the semi-transmission part HA. The second amount of light may be less than the first amount of light.

Thereafter, the method may include removing a portion of the preliminary insulation layer P-50 through the developing of the preliminary insulation layer P-50. The chemical structure of the portion, which overlaps the transmission part FA of the mask MK, of the preliminary insulation layer P-50 may be changed due to the light passing through the transmission part FA, and then dissolved and removed in a developer subsequently provided. That is, regarding the portion of the preliminary insulation layer P-50 which overlaps the transmission part FA of the mask MK, the method may include removing the portion of the preliminary insulation layer P-50 to form a first insulation portion of the insulation layer 50. The first insulation portion may correspond to the groove HP formed by removing the preliminary insulation layer P-50.

An amount of the light emitted onto the portion, which overlaps the semi-transmission part HA of the mask MK, of the preliminary insulation layer P-50 may be less than an amount of the light emitted onto the portion, which overlaps the transmission part FA, of the preliminary insulation layer P-50. The method may include removing the portion of the preliminary insulation layer P-50 in a thickness direction of the preliminary insulation layer P-50 due to the light passing through the semi-transmission part HA and the developer. The method may include removing the portion, which overlaps the semi-transmission part HA of the mask MK, of the preliminary insulation layer P-50 to form a second insulation portion of the insulation layer 50. As the portion overlapping the transmission part FA is exposed to the larger amount of light than the portion overlapping the semi-transmission part HA, the amount removed from the portion overlapping the transmission part FA may be greater than the amount removed from the portion overlapping the semi-transmission part HA. Accordingly, the first insulation portion may have a thickness that is less than the thickness of the second insulation portion. The insulation layer 50 may include the first insulation portion and the second insulation portion that are different in thickness. The first insulation portion may be formed such that the first insulation portion is recessed from the second insulation portion, and the thickness of the first insulation portion may be less than the thickness of the second insulation portion.

In the patterning of the preliminary insulation layer P-50, the method may include forming the insulation layer 50 in which the groove HP is defined from the preliminary insulation layer P-50. The method may include removing a region of the preliminary insulation layer P-50 to form the insulation layer 50 in which the groove HP is defined. For example, as illustrated in FIG. 7C, the method may include defining a first groove HP1 corresponding to the first mask opening portion OP1-M, a second groove HP2 corresponding to the second mask opening portion OP2-M, and a third groove HP3 corresponding to the third mask opening portion OP3-M in the insulation layer 50. The insulation layer 50 in which the groove HP (e.g., first groove HP1, second groove HP2, third groove HP3) is defined may correspond to the fifth insulation layer 50 (see FIG. 5A) described herein with reference to FIG. 5A.

A positive method in which the portion, which is provided with the light, of the preliminary insulation layer P-50 is removed is described as the method for patterning the preliminary insulation layer P-50. However, embodiments supported by the present disclosure are not limited thereto. For example, the preliminary insulation layer P-50 may be patterned using a negative method in which a portion, which is not provided with the light, of the preliminary insulation layer P-50 is removed.

Referring to FIG. 7D, the method for manufacturing the display panel according to an embodiment supported by aspects of the present disclosure may include forming a conductive layer P-AE on the insulation layer 50, and the method may include forming a sacrificial layer P-SP on the conductive layer P-AE. Each of the conductive layer P-AE and the sacrificial layer P-SP may be formed on the base layer BL while filling in the grooves HP1, HP2 and HP3. Each of the conductive layer P-AE and the sacrificial layer P-SP may be formed to have a shape of one body on the base layer BL. Each of the conductive layer P-AE and the sacrificial layer P-SP may be formed using a method of depositing a conductive material. For examples, each of the conductive layer P-AE and the sacrificial layer P-SP may be formed through a sputtering process.

Referring to FIGS. 7E and 7F, the method for manufacturing the display panel according to an embodiment supported by aspects of the present disclosure may include patterning each of the conductive layer P-AE and the sacrificial layer P-SP.

First to third initial photoresist layers PR1-I, PR2-I and PR3-I corresponding to the first to third grooves HP1, HP2 and HP3, respectively, may be formed on the sacrificial layer P-SP. The first to third initial photoresist layers PR1-I, PR2-I and PR3-I may overlap the first to third grooves HP1, HP2 and HP3, respectively, on a plane. The first initial photoresist layer PR1-I may be formed to overlap the first groove HP1, the second initial photoresist layer PR2-I may be formed to overlap the second groove HP2, and the third initial photoresist layer PR3-I may be formed to overlap the third groove HP3.

Thereafter, the first to third initial photoresist layers PR1-I, PR2-I and PR3-I may be used as masks to pattern the conductive layer P-AE and the sacrificial layer P-SP through etching. For example, the first to third initial photoresist layers PR1-I, PR2-I and PR3-I may be used as masks to pattern the conductive layer P-AE and the sacrificial layer P-SP through wet etching. In the patterning of the conductive layer P-AE and the sacrificial layer P-SP, preliminary sacrificial patterns SP1-I, SP2-I and SP3-I may be formed from the sacrificial layer P-SP and first to third anode AE1, AE2 and AE3 may be formed from the conductive layer P-AE. As illustrated in FIG. 7F, the first anode AE1 and the first preliminary sacrificial pattern SP1-I that are stacked in sequence in the third direction DR3 may be defined in the first groove H1, the second anode AE2 and the second preliminary sacrificial pattern SP2-I that are stacked in sequence in the third direction DR3 may be defined in the second groove HP2, and the third anode AE3 and the third preliminary sacrificial pattern SP3-I that are stacked in sequence in the third direction DR3 may be defined in the third groove HP3. The first to third initial photoresist layers PR1-I, PR2-I and PR3-I may be removed after the patterning of the conductive layer P-AE and the sacrificial layer P-SP.

Referring to FIGS. 7G and 7H, the method for manufacturing the display panel according to an embodiment supported by aspects of the present disclosure may include forming a preliminary pixel defining film P-PDL on the insulation layer 50, and patterning the preliminary pixel defining film P-PDL.

Referring to FIG. 7G, the preliminary pixel defining film P-PDL may be formed on the insulation layer 50. The preliminary pixel defining film P-PDL may be disposed on the insulation layer 50 and cover the first to third preliminary sacrificial patterns SP1-I, SP2-I and SP3-I and the first to third anode AE1, AE2 and AE3. The preliminary pixel defining film P-PDL may be formed using a method of depositing an inorganic material. The inorganic material may be deposited onto the insulation layer 50 to form the preliminary pixel defining film P-PDL on the insulation layer 50.

Then, the preliminary pixel defining film P-PDL may be patterned to form a pixel defining film PDL in which first to third emission opening portions OP1-E, OP2-E and OP3-E overlapping the first to third anode AE1, AE2 and AE3, respectively, are defined. The patterning of the preliminary pixel defining film P-PDL may be an operation in which a portion of the preliminary pixel defining film P-PDL is removed through etching. For example, the patterning of the preliminary pixel defining film P-PDL may be performed through dry etching. A region of the preliminary pixel defining film P-PDL may be removed using a method such as, for example, etching, such that the pixel defining film PDL in which the first to third emission opening portions OP1-E, OP2-E and OP3-E are defined is formed. The first emission opening portion OP1-E corresponding to the first anode AE1, the second emission opening portion OP2-E corresponding to the second anode AE2, and the third emission opening portion OP3-E corresponding to the third anode AE3 may be defined in the pixel defining film PDL. Each of the first to third anode AE1, AE2 and AE3 may expose a portion of a top surface of a corresponding preliminary sacrificial pattern of the preliminary sacrificial patterns SP1-I, SP2-I and SP3-I. A portion of a top surface of the first preliminary sacrificial pattern SP1-I may be exposed by the first emission opening portion OP1-E. A portion of a top surface of the second preliminary sacrificial pattern SP2-I may be exposed by the second emission opening portion OP2-E. A portion of a top surface of the third preliminary sacrificial pattern SP3-I may be exposed by the third emission opening portion OP3-E.

Referring to FIG. 7I, the method for manufacturing the display panel according to an embodiment supported by aspects of the present disclosure may include forming a preliminary partition wall P-PW on the insulation layer 50. The forming of the preliminary partition wall P-PW may include forming a first preliminary partition wall layer P-L1 on the pixel defining film PDL, and forming a second preliminary partition wall layer P-L2 on the first preliminary partition wall layer P-L1.

The forming of the first preliminary partition wall layer P-L1 may be performed using a method of depositing a conductive material. In the example embodiment, the conductive material forming the first preliminary partition wall layer P-L1 may include a metal having a low resistance. For example, the conductive material forming the first preliminary partition wall layer P-L1 may be gold (Au), silver (Ag), aluminum (Al), magnesium (Mg), lithium (Li), molybdenum (Mo), copper (Cu), or an alloy thereof. The conductive material forming the first preliminary partition wall layer P-L1 may be aluminum (Al).

Thereafter, the forming of the second preliminary partition wall layer P-L2 on the first preliminary partition wall layer P-L1 may be performed such that the preliminary partition wall P-PW is formed. The forming of the second preliminary partition wall layer P-L2 may be performed using a method of depositing a conductive material. In an embodiment, the conductive material forming the second preliminary partition wall layer P-L2 may include a metal material. For example, the conductive material forming the second preliminary partition wall layer P-L2 may be gold (Au), silver (Ag), aluminum (Al), magnesium (Mg), lithium (Li), molybdenum (Mo), titanium (Ti), copper (Cu), or an alloy thereof. The metal forming the second preliminary partition wall layer P-L2 may be different from the metal forming the first preliminary partition wall layer P-L1. The metal forming the second preliminary partition wall layer P-L2 may include, for example, titanium (Ti).

In an embodiment, the second preliminary partition wall layer P-L2 may not include a metal material. The second preliminary partition wall layer P-L2 may be formed of a silicon-based compound. For example, the second preliminary partition wall layer P-L2 may include at least one of a silicon oxide (SiOₓ), a silicon nitride (SiNₓ), or a silicon oxynitride (SiOₓN_{y}).

The preliminary partition wall P-PW may include the first preliminary partition wall layer P-L1 and the second preliminary partition wall layer P-L2. The first preliminary partition wall layer P-L1 may be formed to have a shape of one body on the insulation layer 50. The second preliminary partition wall layer P-L2 may be formed to have a shape of one body on the insulation layer 50. Each of the first and second preliminary partition wall layers P-L1 and P-L2 may overlap the grooves HP1, HP2 and HP3. Each of the first and second preliminary partition wall layers P-L1 and P-L2 may be formed to have a height difference between a portion overlapping the grooves HP1, HP2 and HP3 and a portion non-overlapping the grooves HP1, HP2 and HP3 in the third direction DR3. Each of the first and second preliminary partition wall layers P-L1 and P-L2 may have a shape in which a region overlapping each of the grooves HP1, HP2 and HP3 is recessed by the height difference with respect to the third direction DR3.

The first preliminary partition wall layer P-L1 may be divided into a plurality of portions. The first preliminary partition wall layer P-L1 may include a first preliminary partition wall portion, which is disposed on the first insulation portion of the insulation layer 50 and has a flat top surface, a second preliminary partition wall portion, which is disposed on the second insulation portion of the insulation layer 50 and has a flat top surface, and a third preliminary partition wall portion which connects the first preliminary partition wall portion to the second preliminary partition wall portion and is inclined at a predetermined angle along an inner side surface of the groove HP defined in the insulation layer 50.

The second preliminary partition wall layer P-L2 may be divided into a plurality of portions. The second preliminary partition wall layer P-L2 may include a fourth preliminary partition wall portion, which is disposed on the first insulation portion of the insulation layer 50 and has a flat top surface, a fifth preliminary partition wall portion, which is disposed on the second insulation portion of the insulation layer 50 and has a flat top surface, and a sixth preliminary partition wall portion which connects the fourth preliminary partition wall portion to the fifth preliminary partition wall portion and is inclined at a predetermined angle along an inner side surface of the groove HP defined in the insulation layer 50.

Referring to FIGS. 7J and 7K, the method for manufacturing the display panel according to an embodiment supported by aspects of the present disclosure may include etching the preliminary partition wall P-PW to form a partition wall PW in which partition wall opening portions OP1-P, OP2-P and OP3-P are defined. The forming of the partition wall PW may include forming a first photoresist pattern PR1 on the preliminary partition wall P-PW, and etching the first preliminary partition wall layer P-L1 and the second preliminary partition wall layer P-L2.

Referring to FIG. 7J, the method for manufacturing the display panel according to an embodiment supported by aspects of the present disclosure may include the forming of the first photoresist pattern PR1 on the preliminary partition wall P-PW. The first photoresist pattern PR1 may be formed by forming a preliminary photoresist layer on the preliminary partition wall P-PW and then patterning the preliminary photoresist layer by using a photo mask. A photo opening portion OP-PR1 overlapping the anode AE may be formed in the first photoresist pattern PR1 through a patterning process. The photo opening portion OP-PR1 may overlap the first to third anode AE1, AE2 and AE3.

The photo opening portion OP-PR1 may overlap the first to third grooves HP1, HP2 and HP3 on a plane. The photo opening portion OP-PR1 defined in the first photoresist pattern PR1 may have a planar area that is less than a planar area of the lowest portion of each of the grooves HP1, HP2 and HP3. That is, the planar area of the photo opening portion OP-PR1 defined in the first photoresist pattern PR1 may be less than a planar area of the second surface UF2-I of the fifth insulation layer 50 described with reference to FIG. 5A. Accordingly, in the etching of the first preliminary partition wall layer P-L1 and the second preliminary partition wall layer P-L2 to be described later herein, a portion of each of the first and second preliminary partition wall layers P-L1 and P-L2, which is disposed in each of the grooves HP1, HP2 and HP3, may remain after the etching. The portion of the second preliminary partition wall layer P-L2, which remains after the etching, may form a tip portion in the partition wall PW.

Then, referring to FIG. 7K, the method for manufacturing the display panel according to an embodiment supported by aspects of the present disclosure may include the etching of the first preliminary partition wall layer P-L1 and the second preliminary partition wall layer P-L2 such that the partition wall PW is formed from the preliminary partition wall P-PW.

The etching of the preliminary partition wall P-PW may be performed twice. The etching of the first preliminary partition wall layer P-L1 and the second preliminary partition wall layer P-L2 may include primary etching and secondary etching.

The primary etching of the first preliminary partition wall layer P-L1 and the second preliminary partition wall layer P-L2 may use the first photoresist pattern PR1 as a mask, and include dry etching the first preliminary partition wall layer P-L1 and the second preliminary partition wall layer P-L2. The primary dry etching according to one or more embodiments may be performed in an etching environment in which etch selectivities of the first preliminary partition wall layer P-L1 and the second preliminary partition wall layer P-L2 are substantially the same. A portion of each of the first preliminary partition wall layer P-L1 and the second preliminary partition wall layer P-L2, which overlaps the photo opening portion OP-PR1, may be etched in the primary dry etching. That is, a portion of the first preliminary partition wall portion of the first preliminary partition wall layer P-L1 described with reference to FIG. 7I may be removed in the primary dry etching. In addition, a portion of the fourth preliminary partition wall portion of the second preliminary partition wall layer P-L2 described with reference to FIG. 7I may be removed in the primary dry etching.

Although not illustrated, a preliminary partition wall opening portion may be formed as the portion of each of the first preliminary partition wall layer P-L1 and the second preliminary partition wall layer P-L2, which overlaps the photo opening portion OP-PR1, is removed after the primary dry etching. Here, an inner side surface of the first preliminary partition wall layer P-L1 and an inner side surface of the second preliminary partition wall layer P-L2, each of which defines the preliminary partition wall opening portion, may be substantially aligned with each other.

The secondary etching of the first preliminary partition wall layer P-L1 may be performed after the primary etching of the first preliminary partition wall layer P-L1 and the second preliminary partition wall layer P-L2. The secondary etching of the first preliminary partition wall layer P-L1 may use the first photoresist pattern PR1 as a mask, and include wet etching the first preliminary partition wall layer P-L1 to form the partition wall opening portions OP1-P, OP2-P and OP3-P. In the present disclosure, the secondary etching of the first preliminary partition wall layer P-L1 may be referred to as an “undercut etching process”.

As illustrated in FIG. 7K, a first partition wall layer L1 and a second partition wall layer L2 may be formed in the secondary etching of the first preliminary partition wall layer P-L1. A remaining portion of the first preliminary partition wall portion of the first preliminary partition wall layer P-L1, and a portion of the third preliminary partition wall portion, which are described with reference to FIG. 7I, may be removed in the secondary etching of the first preliminary partition wall layer P-L1. In the secondary etching of the first preliminary partition wall layer P-L1, the second preliminary partition wall layer P-L2 may not be etched or may not be substantially etched. In the secondary etching of the first preliminary partition wall layer P-L1, an inner side surface of the partition wall PW may have an undercut shape on a cross section as the first preliminary partition wall layer P-L1 is selectively etched. A tip portion may be formed in the partition wall PW by a portion of the second partition wall layer L2, which protrudes from the first partition wall layer L1 toward a center of the anode AE.

The first partition wall layer L1 may have a first inner side surface S1-P that defines a partial region of each of the partition wall opening portions OP1-P, OP2-P and OP3-P. The second partition wall layer L2 may have a second inner side surface S2-P that defines a remaining region of each of the partition wall opening portions OP1-P, OP2-P and OP3-P. The second inner side surface S2-P of the second partition wall layer L2 may have a shape protruding from the first inner side surface S1-P of the first partition wall layer L1 toward a center of each of the anode AE1, AE2 and AE3.

The secondary wet etching according to one or more embodiments may be performed in an etching environment in which a difference in etch selectivity between the first preliminary partition wall layer P-L1 and the second preliminary partition wall layer P-L2 is great. Accordingly, the inner side surface of the partition wall PW, which defines each of the partition wall opening portions OP1-P, OP2-P and OP3-P, may have an undercut shape on a cross section. Specifically, as the first partition wall layer L1 has a higher etch rate for an etchant than an etch rate of the second partition wall layer L2, the first partition wall layer L1 may be more etched than the second partition wall layer L2. Accordingly, the first inner side surface S1-P of the first partition wall layer L1 may be formed to be recessed inward from the second inner side surface S2-P of the second partition wall layer L2. The tip portion may be formed in the partition wall PW by the portion of the second partition wall layer L2, which protrudes from the first partition wall layer L1 toward the center of the anode AE.

Referring to FIGS. 7K and 7L, the method for manufacturing the display panel according to an embodiment supported by aspects of the present disclosure may include etching preliminary sacrificial patterns SP1-I, SP2-I and SP3-I.

The etching of the preliminary sacrificial patterns SP1-I, SP2-I and SP3-I may be performed using a wet etching method, or the preliminary sacrificial patterns SP1-I, SP2-I and SP3-I may be etched using, as a mask, the first photoresist pattern PR1 and the partition wall PW. Sacrificial opening portions OP1-S, OP2-S and OP3-S overlapping the emission opening portions OP1-E, OP2-E and OP3-E may be formed in sacrificial patterns SP1, SP2 and SP3 formed by etching the preliminary sacrificial patterns SP1-I, SP2-I and SP3-I, respectively.

The method for manufacturing the display panel according to an embodiment supported by aspects of the present disclosure may further include etching additionally the pixel defining film PDL before the etching of the preliminary sacrificial patterns SP1-I, SP2-I and SP3-I. The additional etching of the pixel defining film PDL may be performed using a dry etching method, or the pixel defining film PDL may be etched using, as a mask, the first photoresist pattern PR1 and the partition wall PW. A portion of the pixel defining film PDL may be removed through the additional etching. However, embodiments supported by the present disclosure are not limited thereto, and the additional etching of the pixel defining film PDL may be omitted according to conditions for the process.

The sacrificial patterns SP1, SP2 and SP3 may include a first sacrificial pattern SP1, a second sacrificial pattern SP2, and a third sacrificial pattern SP3. A first sacrificial opening portion OP1-S overlapping the first emission opening portion OP1-E may be formed in the first sacrificial pattern SP1, a second sacrificial opening portion OP2-S overlapping the second emission opening portion OP2-E may be formed in the second sacrificial pattern SP2, and a third sacrificial opening portion OP3-S overlapping the third emission opening portion OP3-E may be formed in the third sacrificial pattern SP3. At least a portion of the first anode AE1 may be exposed by the first sacrificial pattern SP1 and the pixel defining film PDL by the first sacrificial opening portion OP1-S and the first emission opening portion OP1-E. At least a portion of the second anode AE2 may be exposed by the second sacrificial pattern SP2 and the pixel defining film PDL by the second sacrificial opening portion OP2-S and the second emission opening portion OP2-E. At least a portion of the third anode AE3 may be exposed by the third sacrificial pattern SP3 and the pixel defining film PDL by the third sacrificial opening portion OP3-S and the third emission opening portion OP3-E.

The etching of the sacrificial patterns SP1, SP2 and SP3 may be performed in an etching environment, in which a difference in etch selectivity between the sacrificial patterns SP1, SP2 and SP3 and the anodes AE1, AE2 and AE3 is great, and accordingly the anodes AE1, AE2 and AE3 may be prevented from being etched together. That is, the sacrificial patterns SP1, SP2 and SP3 having a higher etch rate than the anodes AE1, AE2 and AE3 may be disposed between the pixel defining film PDL and the anodes AE1, AE2 and AE3 such that the anodes AE1, AE2 and AE3 are prevented from being etched together and damaged during the etching.

Thereafter, referring to FIG. 7M, the method for manufacturing the display panel according to an embodiment supported by aspects of the present disclosure may include forming a first light emitting element ED1 by forming a first emission pattern EP1 and a first cathode CE1 in sequence on the first anode AE1 in the first partition wall opening portion OP1-P after the first photoresist pattern PR1 (see FIG. 7L) is removed. The method for manufacturing the display panel according to an embodiment supported by aspects of the present disclosure may further include forming a first capping pattern CP1 on the first light emitting element ED1. The first capping pattern CP1 may be formed to be disposed in the first partition wall opening portion OP1-P.

A first preliminary dummy layer DMP-I may be formed on the partition wall PW in the forming of the first light emitting element ED1. The first preliminary dummy layer DMP-I may be formed through the same processes as the first light emitting element ED1 and the first capping pattern CP1. The first preliminary dummy layer DMP-I may be formed on the partition wall PW and in the second and third partition wall opening portions OP2-P and OP3-P.

The first preliminary dummy layer DMP-I may include a (1-1)-th dummy layer D1-I, a (2-1)-th dummy layer D2-I, and a (3-1)-th dummy layer D3-I. The (1-1)-th dummy layer D1-I may be formed through the same process as the first emission pattern EP1, the (2-1)-th dummy layer D2-I may be formed through the same process as the first cathode CE1, and the (3-1)-th dummy layer D3-I may be formed through the same process as the first capping pattern CP1. The first preliminary dummy layer DMP-I may be formed to be separated from the first light emitting element ED1 and the first capping pattern CP1 by the partition wall PW forming a tip portion.

Then, referring to FIG. 7N, the method for manufacturing the display panel according to an embodiment supported by aspects of the present disclosure may include forming a preliminary lower inorganic encapsulation pattern LIL-I, which covers the first light emitting element ED1, after the forming of the first light emitting element ED1.

The preliminary lower inorganic encapsulation pattern LIL-I may cover the first light emitting element ED1, and cover the first preliminary dummy layer DMP-I. A portion of the first preliminary dummy layer DMP-I may be disposed in the first partition wall opening portion OP1-P. The first preliminary dummy layer DMP-I may be in contact with a top surface of the first capping pattern CP1 and a top surface of the (3-1)-th dummy layer D3-I.

Referring to FIGS. 7N and 7O, the method for manufacturing the display panel according to an embodiment supported by aspects of the present disclosure may include patterning the preliminary lower inorganic encapsulation pattern LIL-I and the first preliminary dummy layer DMP-I. The patterning of the preliminary lower inorganic encapsulation pattern LIL-I and the first preliminary dummy layer DMP-I may include forming a second photoresist pattern PR2, patterning the preliminary lower inorganic encapsulation pattern LIL-I such that a lower inorganic encapsulation pattern LIL is formed, and patterning the first preliminary dummy layer DMP-I such that dummy patterns DMP1 are formed.

In the forming of the second photoresist pattern PR2, the second photoresist pattern PR2 may be formed by forming a second preliminary photoresist layer, and then patterning the second preliminary photoresist layer by using a photo mask. The second photoresist pattern PR2 may be formed to have a pattern shape corresponding to the first emission opening portion OP1-E through the patterning process.

In the patterning of the preliminary lower inorganic encapsulation pattern LIL-I, dry etching may be performed on the preliminary lower inorganic encapsulation pattern LIL-I that a portion, which does not overlap the second photoresist pattern PR2, of the preliminary lower inorganic encapsulation pattern LIL-I is removed. That is, the preliminary lower inorganic encapsulation pattern LIL-I may be patterned such that a portion, which does not overlap the first anode AE1, of the preliminary lower inorganic encapsulation pattern LIL-I is removed. A first lower inorganic encapsulation pattern LIL1 overlapping the first emission opening portion OP1-E may be formed from the patterned preliminary lower inorganic encapsulation pattern LIL-I.

In the patterning of the first preliminary dummy layer DMP-I, dry etching may be performed on the (1-1)-th dummy layer D1-I, the (2-1)-th dummy layer D2-I, and the (3-1)-th dummy layer D3-I such that a portion, which does not overlap the second photoresist pattern PR2, of each of the (1-1)-th dummy layer D1-I, the (2-1)-th dummy layer D2-I, and the (3-1)-th dummy layer D3-I is removed. That is, the first preliminary dummy layer DMP-I may be patterned such that a portion, which does not overlap the first anode AE1, of each of the (1-1)-th dummy layer D1-I, the (2-1)-th dummy layer D2-I, and the (3-1)-th dummy layer D3-I is removed. (1-1)-th, (2-1)-th, and (3-1)-th dummy patterns D11, D21 and D31 that overlap the first emission opening portion OP1-E may be formed from the patterned (1-1)-th, (2-1)-th, and (3-1)-th dummy layers D1-I, D2-I and D3-I, respectively. The (1-1)-th, (2-1)-th, and (3-1)-th dummy patterns D11, D21 and D31 may have a closed line shape surrounding a corresponding emission area PXA (see FIG. 5A) on a plane.

The patterning of the first preliminary dummy layer DMP-I may further include wet etching the (1-1)-th, (2-1)-th, and (3-1)-th dummy layers D1-I, D2-I and D3-I after the dry etching of the (1-1)-th, (2-1)-th, and (3-1)-th dummy layers D1-I, D2-I and D3-I.

The patterning of the first preliminary dummy layer DMP-I may be performed such that a portion, which does not overlap the first anode AE1, of the first preliminary dummy layer DMP-I is removed. The first preliminary dummy layer DMP-I formed in the second and third partition wall opening portions OP2-P and OP3-P may be removed through the patterning process. In addition, the (1-1)-th to (3-1)-th dummy layers D1-I, D2-I and D3-I, which are formed on the partition wall PW non-overlapping the first emission opening portion OP1-E, may also be removed through the patterning process. The first emission pattern EP1 and the first cathode CE1 that overlap the first emission opening portion OP1-E may formed from the patterned first preliminary dummy layer DMP-I. The first anode AE1, the first emission pattern EP1, and the first cathode CE1, which are formed in the first emission opening portion OP1-E and the first partition wall opening portion OP1-P, may constitute the first light emitting element ED1 after the patterning process.

Referring to FIG. 7P, the method for manufacturing the display panel according to an embodiment supported by aspects of the present disclosure may include forming a second light emitting element ED2 and a third light emitting element ED3. The second light emitting element ED2 and the third light emitting element ED3 may be formed in sequence after the second photoresist pattern PR2 (see FIG. 7O) is removed. The forming of the second light emitting element ED2 and the third light emitting element ED3 may be substantially the same as the forming of the first light emitting element ED1 described with reference to FIGS. 7M to 7O. Accordingly, the display panel DP may be formed which includes the first to third light emitting elements ED1, ED2 and ED3, the first to third dummy patterns D1, D2 and D3, and the first to third lower inorganic encapsulation patterns LIL1, LIL2 and LIL3, which correspond to the plurality of emission areas PXA-R, PXA-G and PXA-B illustrated in FIG. 5D, respectively.

Thereafter, referring to FIG. 7Q, the method for manufacturing the display panel according to an embodiment supported by aspects of the present disclosure may include forming an organic encapsulation film OL on the inorganic patterns LIL1, LIL2 and LIL3 and the partition wall PW, and forming an upper inorganic encapsulation film UIL on the organic encapsulation film OL. The organic encapsulation film OL and the upper inorganic encapsulation film UIL may be formed on the inorganic patterns LIL1, LIL2 and LIL3 such that the display panel DP including an encapsulation layer TFE is finished.

Accordingly, the display panel DP including the base layer BL, the circuit element layer D-CL, the insulation layer 50, the display element layer D-OL, and the encapsulation layer TFE may be formed.

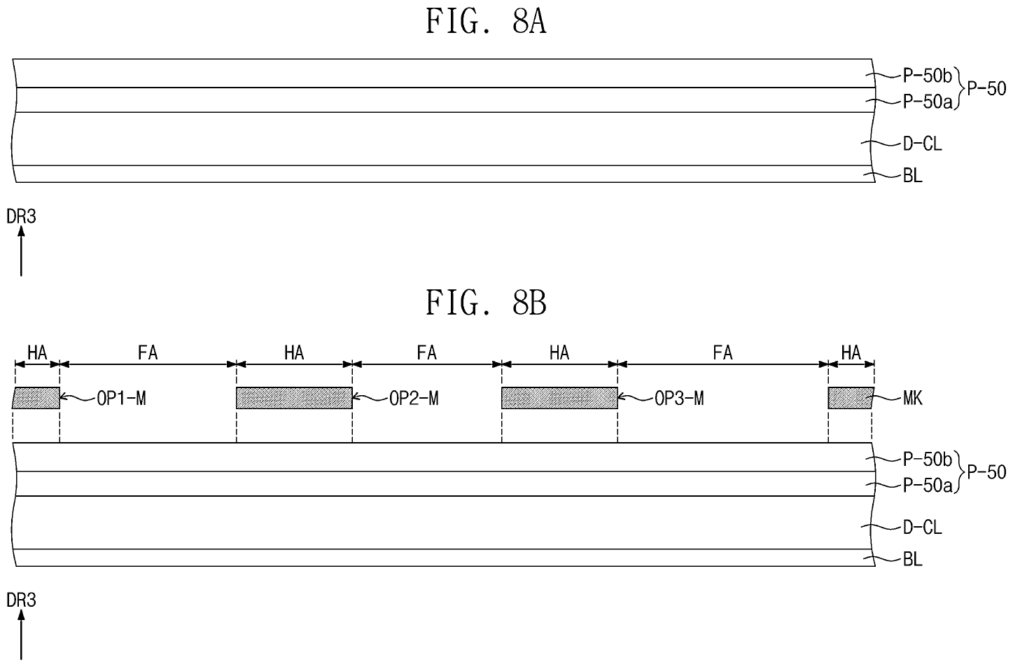

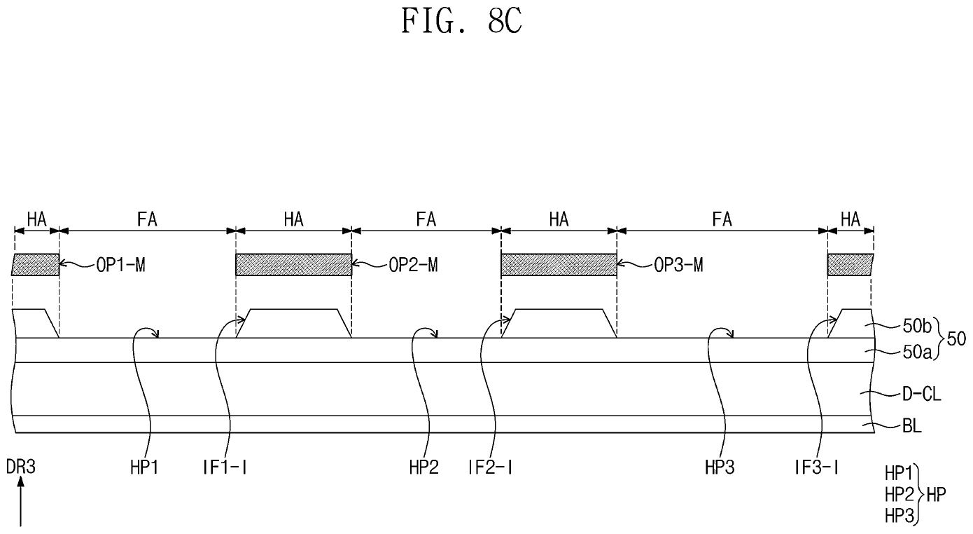

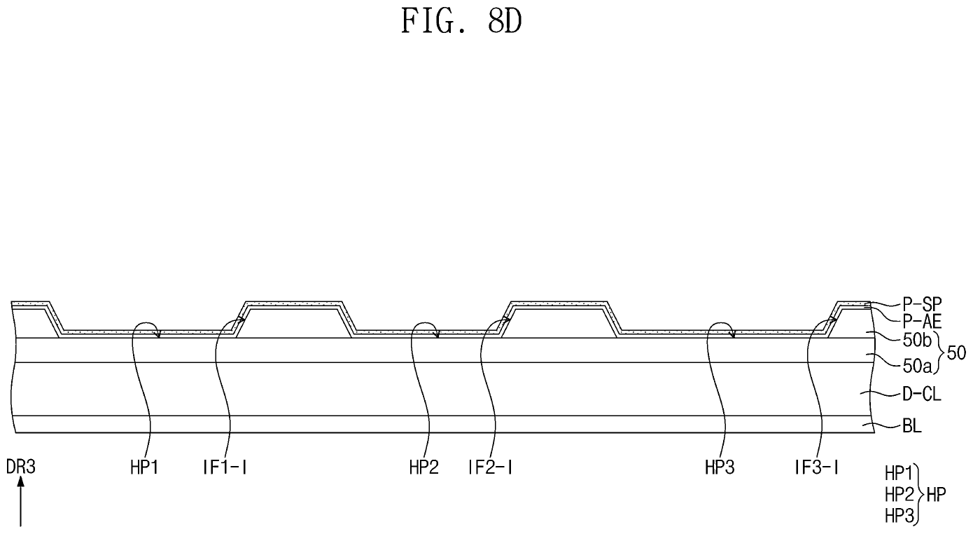

FIGS. 8A to 8D are cross-sectional views illustrating some operations of a method for manufacturing a display panel according to an embodiment supported by aspects of the present disclosure. Hereinafter, the method for manufacturing the display panel according to an embodiment supported by aspects of the present disclosure will be described with reference to FIGS. 8A to 8D. The same/similar components as/to those described herein are denoted as the same/similar reference numbers or symbols, and the detailed descriptions thereof are omitted.

The method for manufacturing the display panel illustrated in FIGS. 8A to 8D is different in that an insulation layer 50 has a two-layer structure, when compared to the method for manufacturing the display panel described with reference to FIGS. 7A to 7Q.

Referring to FIG. 8A, the method for manufacturing the display panel according to an embodiment supported by aspects of the present disclosure may include forming a preliminary insulation layer P-50 on the base layer BL. The forming of the preliminary insulation layer P-50 may include forming a preliminary lower film P-50a on the base layer BL, and forming a preliminary upper film P-50b on the preliminary lower film P-50a. Each of the preliminary lower film P-50a and the preliminary upper film P-50b may be formed using various methods such as, for example, coating or deposition.

Referring to FIGS. 8B and 8C, the method for manufacturing the display panel according to an embodiment supported by aspects of the present disclosure may include patterning the preliminary insulation layer P-50 to form the insulation layer 50 in which a groove HP is defined. The patterning of the preliminary insulation layer P-50 may be performed after the forming of the preliminary insulation layer P-50. The patterning of the preliminary insulation layer P-50 may include emitting light toward the preliminary upper film P-50b and developing the preliminary upper film P-50b. Accordingly, for example, the patterning of the preliminary insulation layer P-50 may include exposing the preliminary upper film P-50b to light by using a mask MK described herein.

The mask MK may be provided on the preliminary upper film P-50b to pattern the preliminary upper film P-50b. First to third mask opening portions OP1-M, OP2-M and OP3-M may be defined in the mask MK used in an exposure process for the preliminary upper film P-50b. The mask MK may include a transmission part FA and a blocking part HA. The transmission part FA may be a region overlapping the first to third mask opening portions OP1-M, OP2-M and OP3-M. Light, which passes through the mask opening portions OP1-M, OP2-M and OP3-M, of the supplied light may be supplied to a portion, which overlaps each of the mask opening portions OP1-M, OP2-M and OP3-M, of the preliminary upper film P-50b. The blocking part HA of the mask MK may block the supplied light. The light may not be supplied to a portion, which overlaps the blocking part HA, of the preliminary upper film P-50b.

Thereafter, the portion, which overlaps each of the mask opening portions OP1-M, OP2-M and OP3-M, of the preliminary upper film P-50b may be removed through the developing of the preliminary upper film P-50b exposed to the light. Accordingly, the insulation layer 50 in which first to third inner side surfaces IF1-I, IF2-I and IF3-I corresponding to the first to third mask opening portions OP1-M, OP2-M and OP3-M, respectively, are defined may be formed. The first to third inner side surfaces IF1-I, IF2-I and IF3-I may be formed by passing through an upper film 50b from a top surface to a bottom surface. A portion of a top surface of a lower film 50a may be exposed by the first to third inner side surfaces IF1-I, IF2-I and IF3-I.

The insulation layer 50 in which the groove HP is defined may be formed in the patterning of the preliminary insulation layer P-50. The insulation layer 50 may include the lower film 50a, which is disposed on a circuit element layer D-CL and has a uniform thickness, and the upper film 50b which is disposed on the lower film 50a and defined by the first to third inner side surfaces IF1-I, IF2-I and IF3-I.

The first inner side surface IF1-I of the upper film 50b and a top surface of the lower film 50a, which is exposed by the first inner side surface IF1-I, may form a first groove HP1 of the insulation layer 50. The second inner side surface IF2-I of the upper film 50b and the top surface of the lower film 50a, which is exposed by the second inner side surface IF2-I, may form a second groove HP2 of the insulation layer 50. The third inner side surface IF3-I of the upper film 50b and the top surface of the lower film 50a, which is exposed by the third inner side surface IF3-I, may form a third groove HP3 of the insulation layer 50.

Referring to FIG. 8D, the method for manufacturing the display panel according to an embodiment supported by aspects of the present disclosure may include forming a conductive layer P-AE on the insulation layer 50 and forming a sacrificial layer P-SP on the conductive layer P-AE. Each of the conductive layer P-AE and the sacrificial layer P-SP may be formed on the base layer BL while filling in the grooves HP1, HP2 and HP3. The method may include forming each of the conductive layer P-AE and the sacrificial layer P-SP to have a shape of one body on the base layer BL. The method may include using a method of depositing a conductive material in association with forming each of the conductive layer P-AE and the sacrificial layer P-SP. For example, the method may include forming each of the conductive layer P-AE and the sacrificial layer P-SP through a sputtering process.

Thereafter, the method may include forming the base layer BL, the circuit element layer D-CL, the insulation layer 50, first to third anode AE1, AE2 and AE3, first to third sacrificial patterns SP1, SP2 and SP3, a pixel defining film PDL, a partition wall PW, a lower inorganic encapsulation pattern LIL, an organic encapsulation film OL, and an upper inorganic encapsulation film UIL using the same techniques and methods described with reference to FIGS. 7E and 7F, such that the display panel DP illustrated in FIG. 6B is formed.

According to a display panel according to an embodiment supported by aspects of the present disclosure, a tip portion of a partition wall may include a portion inclined at a predetermined angle such that step coverage in which an organic matter is deposited onto an inner side surface of the partition wall along a bottom surface of the tip portion is prevented to improve reliability of the display panel.

Embodiments of the present disclosure support one or more processes (methods, flowcharts) supportive of the features and embodiments described herein. Descriptions that an element “may be disposed,” “may be formed,” “may be stacked,” “may be etched,” and the like include processes (methods, flowcharts) for disposing, forming, positioning, stacking, or modifying the element, and the like, in accordance with example aspects described herein.

Although the embodiments supported by aspects of the present disclosure have been described, it is understood that the example aspects described herein should not be limited to these embodiments but various changes and modifications can be made by one ordinary skilled in the art within the spirit and scope of the present disclosure as hereinafter claimed. Therefore, the technical scope supported by aspects of the present disclosure is not limited to the contents described in the detailed description of the specification, but should be determined by the claims.

What is claimed is:

1. A display panel comprising:
a base layer in which an emission area and a peripheral area adjacent to the emission area are defined;
an insulation layer disposed on the base layer and in which a groove overlapping the emission area is defined;
a pixel defining film disposed on the insulation layer and in which an emission opening portion overlapping the groove is defined;
a partition wall disposed on the pixel defining film and in which a partition wall opening portion overlapping the emission opening portion is defined; and
a light emitting element disposed in the partition wall opening portion, the light emitting element comprising an anode, an intermediate layer, and a cathode that is in contact with the partition wall,
wherein the insulation layer comprises an inner side surface defining the groove and inclined at a first angle with respect to a top surface of the base layer,
wherein at least a portion of the partition wall has a shape extending along the inner side surface.

2. The display panel of claim 1, wherein the partition wall comprises a tip portion extending along the inner side surface and protruding toward a center of the anode.

3. The display panel of claim 2, wherein the tip portion comprises:
a first tip portion extending along the inner side surface and inclined at a second angle with respect to the top surface of the base layer; and
a second tip portion extending from the first tip portion in a direction parallel to the top surface of the base layer.

4. The display panel of claim 3, wherein the second angle is substantially equal to the first angle.

5. The display panel of claim 1, wherein the partition wall comprises:
a first partition wall layer disposed on the pixel defining film and in contact with the cathode; and
a second partition wall layer disposed on the first partition wall layer and comprising a tip portion protruding from an inner side surface of the first partition wall layer.

6. The display panel of claim 5, wherein the second partition wall layer comprises:
a first portion overlapping the peripheral area and having a flat top surface;
a second portion extending from the first portion along the inner side surface; and
a third portion extending from the second portion in a direction parallel to the top surface of the base layer,
wherein a sub-portion of the second portion and a sub-portion of the third portion define the tip portion.

7. The display panel of claim 6, wherein the first partition wall layer comprises:
a first partition wall portion disposed between the first portion and the pixel defining film; and
a second partition wall portion disposed between the second portion and the inner side surface.

8. The display panel of claim 6, wherein a length of the tip portion is about 0.6 μm to about 1.5 μm.

9. The display panel of claim 1, wherein at least a portion of the pixel defining film has a shape extending along the inner side surface.

10. The display panel of claim 9, further comprising a sacrificial pattern disposed in the groove, and between the anode and the pixel defining film, and in which a sacrificial opening portion overlapping the emission opening portion is defined.

11. The display panel of claim 1, wherein the insulation layer comprises a top surface comprising:
a first surface overlapping the peripheral area; and
a second surface having a height difference with the first surface and defining the groove together with the inner side surface.

12. The display panel of claim 1, further comprising an encapsulation layer disposed on the light emitting element and comprising a plurality of thin films,
wherein the encapsulation layer comprises an inorganic encapsulation pattern covering the light emitting element and including a portion that is in contact with the partition wall.

13. The display panel of claim 1, further comprising:
a first dummy pattern disposed on the partition wall and comprising a same material as an emission pattern included in the display panel, wherein the first dummy pattern is spaced apart from the emission pattern; and
a second dummy pattern disposed on the first dummy pattern and comprising a same material as the cathode, wherein the second dummy pattern is spaced apart from the cathode.

14. A display panel comprising:
a base layer in which an emission area and a peripheral area adjacent to the emission area are defined;
an anode disposed on the base layer;
a pixel defining film in which an emission opening portion exposing at least a portion of the anode and overlapping the emission area is defined;
a partition wall disposed on the pixel defining film and in which a partition wall opening portion overlapping the emission opening portion is defined;
an emission pattern disposed in the partition wall opening portion; and
a cathode that is disposed in the partition wall opening portion and is in contact with the partition wall,
wherein the partition wall comprises a tip portion protruding toward a center of the anode,
wherein the tip portion comprises:
a first tip portion inclined at a predetermined angle with respect to a top surface of the base layer; and
a second tip portion extending from the first tip portion in a direction parallel to the top surface of the base layer.

15. A method for manufacturing a display panel, the method comprising:
preparing a base layer in which an emission area and a peripheral area adjacent to the emission area are defined;
forming, on the base layer, an insulation layer in which a groove overlapping the emission area is defined;
forming an anode in the groove defined in the insulation layer;
forming, on the insulation layer, a pixel defining film in which an emission opening portion overlapping the anode is defined;
forming, on the pixel defining film, a partition wall in which a partition wall opening portion overlapping the emission opening portion is defined;
forming an emission pattern comprising at least a portion disposed in the emission opening portion; and
forming a cathode comprising at least a portion disposed in the partition wall opening portion, wherein the cathode is in contact with an inner side surface of the partition wall that defines the partition wall opening portion,
wherein the insulation layer comprises an inner side surface configured to define the groove and inclined at a first angle with respect to a top surface of the base layer,
wherein at least a portion of the partition wall has a shape extending along the inner side surface.

16. The method of claim 15, wherein the forming of the anode comprises:
forming a conductive layer on the insulation layer; and
patterning the conductive layer such that the anode overlapping the groove is formed.

17. The method of claim 15, further comprising, before the forming of the pixel defining film, forming a preliminary sacrificial pattern on the anode,
wherein the forming of the anode and the forming of the preliminary sacrificial pattern are performed through a same process.

18. The method of claim 17, wherein the forming of the anode and the preliminary sacrificial pattern comprises:
forming a conductive layer on the insulation layer;
forming a sacrificial layer on the conductive layer; and
patterning the conductive layer and the sacrificial layer such that the anode and the preliminary sacrificial pattern are formed, wherein the anode and the preliminary sacrificial pattern overlap the groove.

19. The method of claim 18, further comprising forming the sacrificial pattern in which a sacrificial opening portion overlapping the partition wall opening portion is defined, wherein the forming of the sacrificial pattern comprises etching the preliminary sacrificial pattern and is after the forming of the partition wall.

20. The method of claim 15, wherein the forming of the insulation layer comprises:
forming a preliminary insulation layer on the base layer;
exposing the preliminary insulation layer to light by using a mask in which a transmission area corresponding to the emission area and a semi-transmission area corresponding to the peripheral area are defined; and
developing the preliminary insulation layer.
